(19) United States
(12) Patent Application Publication
(10) Pub. No.: US 2024/0356322 A1
(43) Pub. Date: Oct. 24, 2024

(54) SIGNAL LOOP BUSBARS AND SEMICONDUCTOR POWER MODULES INCLUDING THE SAME AND PROCESSES OF IMPLEMENTING THE SAME

(71) Applicant: WOLFSPEED, INC., Durham, NC (US)

(72) Inventor: Amol DESHPANDE, Fayetteville, AR (US)

(21) Appl. No.: 18/305,976

(22) Filed: Apr. 24, 2023

(51) Int. Cl. H02G 5/02; H05K 7/02

(52) U.S. Cl. CPC H02G 5/02; H05K 7/02

(57) ABSTRACT

A power module having a plurality of bus bars. The power module and/or bus bars being configured with features to reduce inductance; and/or the power module and/or bus bars are configured with features to have a substantially equivalent inductance.

### BACKGROUND OF THE DISCLOSURE

As will be appreciated by those skilled in the art, power modules are known in various forms. Power modules provide a physical containment for power components, usually power semiconductor devices. The power semiconductors are typically arranged on a power electronic substrate. The power module typically carries the power semiconductors, provides electrical and thermal contact, and includes electrical insulation.

Current trends are placing increasing demands on power modules including the power semiconductor devices, power electronics, and/or the like associated with the power modules. For example, improved efficiency, improved operation, higher power density, and/or the like. These demands extend from the system level down to the component level. In this regard, an inductance of signal loop busbars may have a detrimental impact upon operation of the power module.

Accordingly, what is needed are signal loop busbars configured to address issues relating to inductance and/or the like as described herein.

### SUMMARY OF THE DISCLOSURE

The foregoing needs are met, to a great extent, by the disclosure, wherein a semiconductor power module having matched and low inductance signal loop busbars, processes of implementing a semiconductor power module having matched and low inductance signal loop busbars, and processes of manufacturing a semiconductor power module having matched and low inductance signal loop busbars are disclosed.

In one aspect, a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the high side Kelvin bus bar, the high side gate bus bar, the low side Kelvin bus bar, and the low side gate bus bar are configured and arranged such that a high side signal loop inductance and a low side signal loop inductance are substantially equivalent.

In one aspect, a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the low side gate bus bar and the low side Kelvin bus bar are arranged with a uniform gap therebetween to reduce a low side signal loop inductance. The power module also includes where the high side gate bus bar and the high side Kelvin bus bar are arranged with a uniform gap therebetween to reduce a high side signal loop inductance.

In one aspect, a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where one or more upper surfaces of the low side Kelvin bus bar and the low side gate bus bar are within a same plane to reduce a low side signal loop inductance. The power module also includes where one or more lower surfaces of the low side Kelvin bus bar and the low side gate bus bar are within a same plane to reduce a low side signal loop inductance. The power module further includes where one or more upper surfaces of the high side Kelvin bus bar and the high side gate bus bar are arranged in a same plane to lower a high side signal loop inductance. The power module in addition includes where one or more lower surfaces of the high side Kelvin bus bar and the high side gate bus bar are arranged in a same plane to lower a high side signal loop inductance.

In one aspect, a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes configuring and arranging the high side Kelvin bus bar, the high side gate bus bar, the low side Kelvin bus bar, and the low side gate bus bar such that a high side signal loop inductance and a low side signal loop inductance are substantially equivalent.

In one aspect, a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes configuring and arranging the low side gate bus bar and the low side Kelvin bus bar with a uniform horizontal gap therebetween to reduce a low side signal loop inductance. The process also includes configuring and arranging the high side gate bus bar and the high side Kelvin bus bar with a uniform horizontal gap therebetween to reduce a high side signal loop inductance.

In one aspect, a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes arranging one or more upper surfaces of the low side Kelvin bus bar and the low side gate bus bar within a same plane to reduce a low side signal loop inductance. The process also includes arranging one or more lower surfaces of the low side Kelvin bus bar and the low side gate bus bar within a same plane to reduce a low side signal loop inductance. The process further includes arranging one or more upper surfaces of the high side Kelvin bus bar and the high side gate bus bar within a same plane to lower a high side signal loop inductance. The process in addition includes arranging one or more lower surfaces of the high side Kelvin bus bar and the high side gate bus bar within in a same plane to lower a high side signal loop inductance.

In one aspect, a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the high side Kelvin bus bar, the high side gate bus bar, the low side Kelvin bus bar, and the low side gate bus bar each include at least one lateral portion and at least one longitudinal portion. The power module also includes where a vertical dimension of the at least one lateral portion and the at least one longitudinal portion is at least 20% of a power module vertical height.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a top view of a power module according to aspects of the disclosure.

FIG. 2 illustrates a partial perspective view of the power module according to FIG. 1.

FIG. 3 illustrates a partial top view of the power module according to FIG. 2.

FIG. 4 illustrates a partial equivalent circuit diagram of the power module according to FIG. 2.

FIG. 5 illustrates a perspective view of the low side Kelvin bus bar and the low side gate bus bar according to aspects of the disclosure.

FIG. 6 illustrates a top view of the low side Kelvin bus bar and the low side gate bus bar according to aspects of the disclosure.

FIG. 7 illustrates a partial perspective view of the high side Kelvin bus bar and the high side gate bus bar according to aspects of the disclosure.

FIG. 8 illustrates a partial top view of the high side Kelvin bus bar and the high side gate bus bar according to FIG. 7.

FIG. 9 illustrates a cross-sectional side view of the low side Kelvin bus bar and the low side gate bus bar according to aspects of the disclosure.

FIG. 10 illustrates a side view of the low side Kelvin bus bar and the low side gate bus bar according to aspects of the disclosure.

FIG. 11 illustrates another side view of the low side Kelvin bus bar and the low side gate bus bar according to aspects of the disclosure.

FIG. 12 illustrates a cross-sectional side view of the high side Kelvin bus bar and the high side gate bus bar according to aspects of the disclosure.

FIG. 13 illustrates a side view of the high side Kelvin bus bar and the high side gate bus bar according to aspects of the disclosure.

FIG. 14 illustrates a process of manufacturing a power module according to aspects of the disclosure.

### DETAILED DESCRIPTION

The disclosure will now be described with reference to the drawing figures, in which like reference numerals refer to like parts throughout. Aspects of the disclosure advantageously provide a semiconductor power module having matched and low inductance signal loop busbars, processes of implementing a semiconductor power module having matched and low inductance signal loop busbars, and processes of manufacturing a semiconductor power module having matched and low inductance signal loop busbars.

The disclosure is directed to a power module that may implement a co-molding technology to embed laminated conductive busbars within plastic parts thereof. In particular, the disclosed power module exploits this co-molding technology to route gate and Kelvin source signals, which switch the devices, such as silicon carbide MOSFETs (Metal Oxide Semiconductor Field Effect Transistors), on and off, from their external pinouts (terminals) accessible on the power module's plastic case to the devices within the power module. A half-bridge power module consists of two signal loops, one for the high side (HS) switch and another for the low side (LS). In particular, the disclosure may optimize the laminated busbars' length (i.e., path), width, and spacing to achieve low inductances for both signal loops. Additionally, the disclosed power module further optimizes the laminated busbars to match the inductances of these two signal loops. In this regard, a same value of inductance for upper and lower switches may be beneficial.

Further, a mismatch in gate inductance between upper and lower switch should be low. Mathematically, we seek to drive the mismatch of the HS and LS of the G-SK (Gate-Source Kelvin) loop impedances to zero:

$$min \{ {Z}_{G - SK}^{HS} - {Z}_{G - SK}^{LS} \} = {Z}_{G - SK}^{HS} - {Z}_{G - SK}^{LS} \to 0$$

where Z_{GS-K}^{HS}=R_{GS-K}^{HS}+jωL_{GS-K}^{HS} and Z_{GS-K}^{LS}=R_{GS-K}^{LS}+jω_{GS-K} ^{LS} are the HS and LS impedances, respectively.

Consequently, the LS and HS devices, such as MOSFETs, would switch homogeneously (i.e., assuming identical device characteristics in the switch position).

Aspects of the disclosure may be even more critical for power modules where the pinouts are not arranged symmetrically on the power module. Aspects of the disclosure may circumvent this problem of asymmetry when implementing devices such as SiC MOSFET devices in such power modules.

Typically, routing is implemented with a few different combinations of terminals, aluminum wires, printed-circuit boards (PCBs), Direct Bonded Copper (DBC) substrate traces, Active Metal Brazed (AMB) substrate traces, and/or the like. The busbars of the disclosure fundamentally replace PCBs, which limit the routing in 2-D space. Busbars allow 3-D routing facilitated by the possibility to bend them at multiple locations. A PCB would be an extra component in the bill of materials (BOM) to manage. In contrast, embedding busbars in the plastic sidewalls reduces the BOM.

Aspects of the disclosure implement the busbars via an optimization of the length, width, and spacing, aided by finite-element simulation. Further, aspects of the disclosure account for constraints from the co-molding injection process and industry-standard module footprint and pinouts. The optimized busbar of the disclosure concurrently may achieve near perfect matching and significantly lower inductances. This results in an approximate 75.3% and 67.5% reduction in HS and LS inductances respectively for some applications. This improvement may result in faster signal propagation from a gate driver to device gates, faster charging of an input capacitance, quicker device turn-on, and increases a resonant frequency of the G-SK loops (i.e., with Ls and input capacitance). At resonance the G-SK loop impedance would be equal to or approach Z=RG.

The disclosure is applicable to any power module type including power modules with multiple switch positions in their configuration, such as a two-level half-bridge, a three-level active neutral point clamped (ANPC) topology, and/or others.

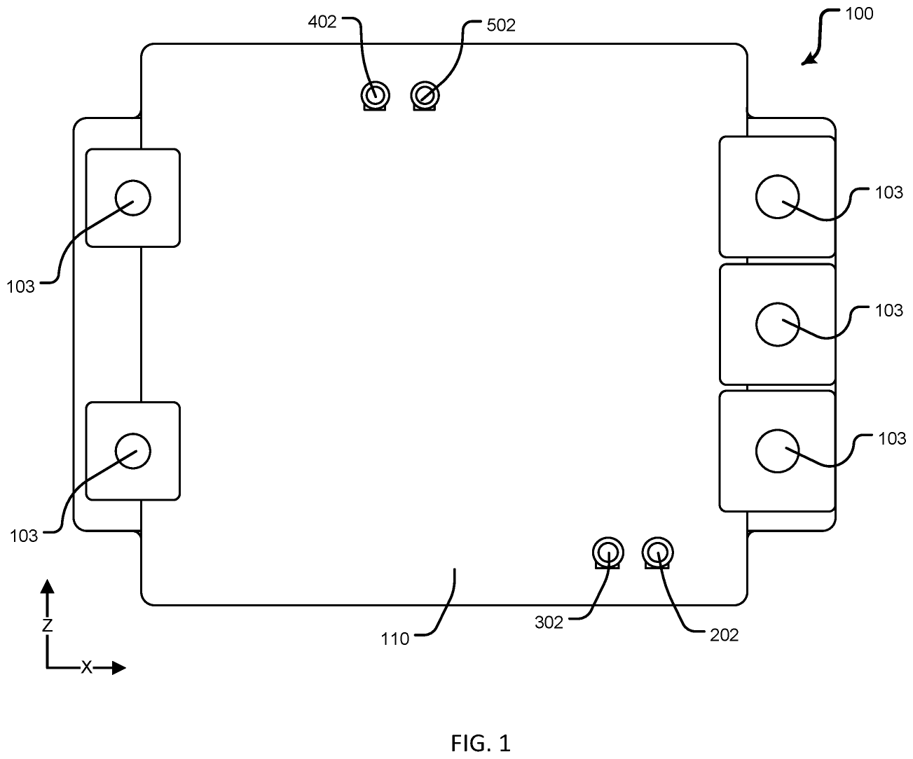

FIG. 1 illustrates a top view of a power module according to aspects of the disclosure.

In particular, FIG. 1 illustrates a top view of a power module 100 according to aspects of the disclosure. The power module 100 may include power terminals 103, a high side Kelvin terminal 202, a high side gate terminal 302, a low side Kelvin terminal 402, a low side gate terminal 502, a housing 110, and/or the like.

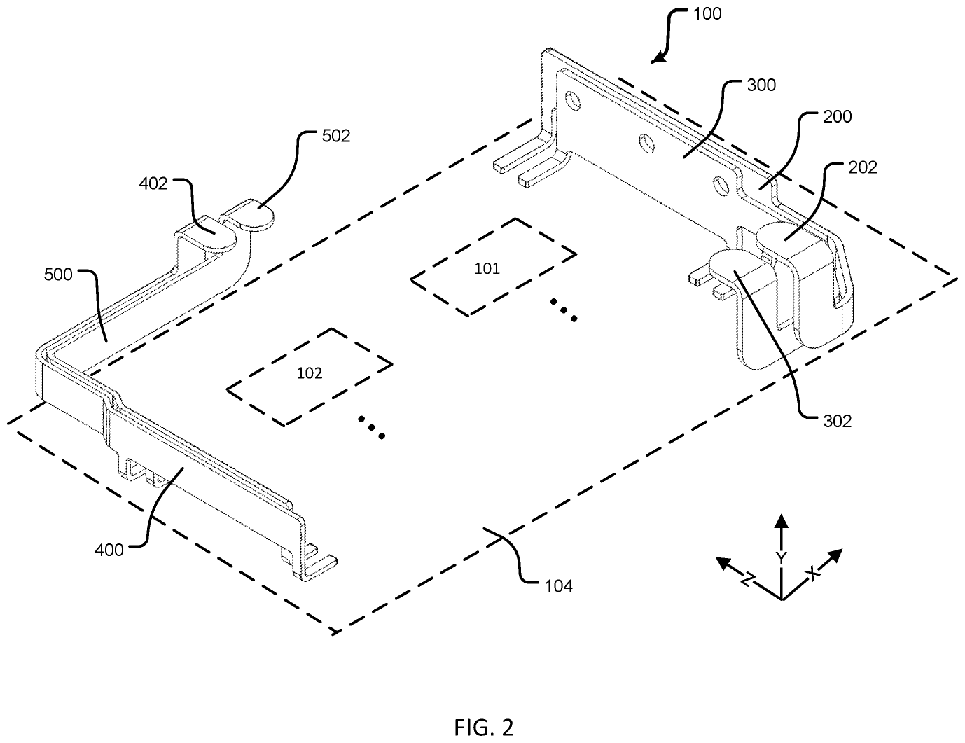

FIG. 2 illustrates a partial perspective view of the power module according to FIG. 1.

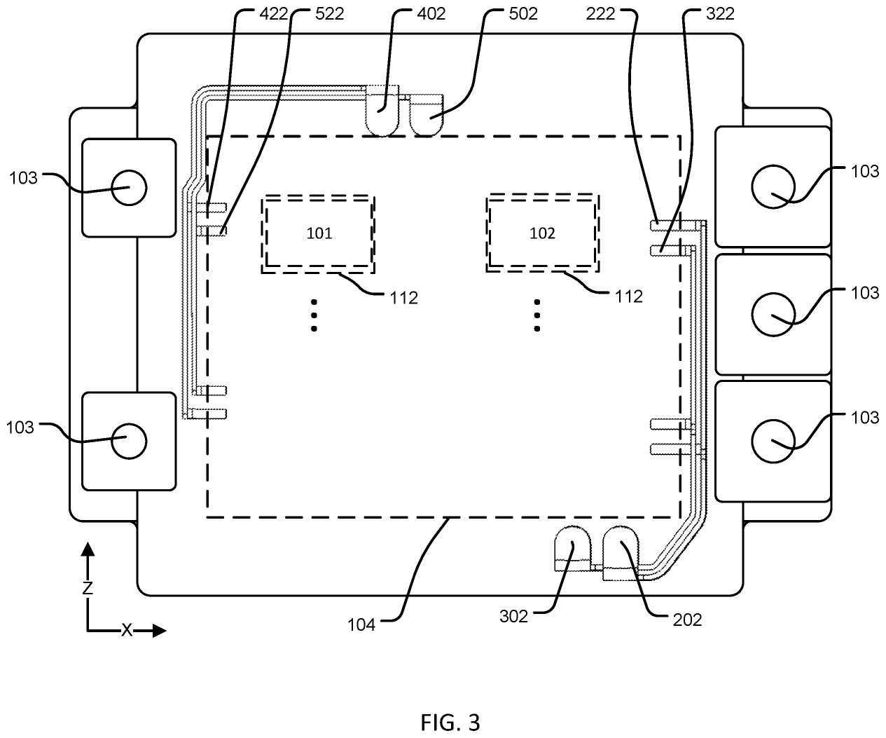

FIG. 3 illustrates a partial top view of the power module according to FIG. 2.

As illustrated in FIG. 2, the power module 100 is illustrated without various components to aid in understanding. The power module 100 may include a high side Kelvin bus bar 200, a high side gate bus bar 300, a low side Kelvin bus bar 400, a low side gate bus bar 500, and/or the like. Further, the power module 100 may include at least one first position device 101 and at least one second position device 102 (illustrated schematically).

The at least one first position device 101 and the at least one second position device 102 may be arranged on a substrate 104 (illustrated schematically). Moreover, the at least one first position device 101 and the at least one second position device 102 may be attached to the substrate 104 by a component attach 112. Additionally, portions of the high side Kelvin bus bar 200, the high side gate bus bar 300, the low side Kelvin bus bar 400, and the low side gate bus bar 500 may also be attached to the substrate 104 by the component attach 112 (not shown).

In aspects, the housing 110 (illustrated in FIG. 1) may be implemented with a molding compound, a molded material, a co-molding technology, and/or the like to embed laminated implementations of the high side Kelvin bus bar 200, the high side gate bus bar 300, the low side Kelvin bus bar 400, and/or the low side gate bus bar 500 within the housing 110. In particular aspects, the power module 100 may exploit this co-molding technology to route the gate signals and Kelvin source signals with the high side Kelvin bus bar 200, the high side gate bus bar 300, the low side Kelvin bus bar 400, and/or the low side gate bus bar 500, which switch the at least one first position device 101 and the at least one second position device 102 on and off. In aspects, signals may be received by the high side Kelvin terminal 202, the high side gate terminal 302, the low side Kelvin terminal 402, and/or the low side gate terminal 502. The signals may be transferred through the high side Kelvin bus bar 200, the high side gate bus bar 300, the low side Kelvin bus bar 400, and the low side gate bus bar 500. Thereafter, the signals may be transferred to the substrate 104 by high side Kelvin connections 222, high side gate connections 322, low side Kelvin connections 422, and/or low side gate connections 522 as illustrated in FIG. 3.

In particular, the power module 100 may optimize various components of the high side Kelvin bus bar 200, the high side gate bus bar 300, the low side Kelvin bus bar 400, and/or the low side gate bus bar 500 including length, path, width, spacing, and/or the like to achieve low inductances for both signal loops. Additionally, the disclosed implementation of the power module 100 may further optimize the high side Kelvin bus bar 200, the high side gate bus bar 300, the low side Kelvin bus bar 400, and/or the low side gate bus bar 500 to match the inductances of these two signal loops. Consequently, the at least one first position device 101 and the at least one second position device 102 may switch homogeneously or switch more homogeneously, assuming identical device characteristics in the switch position.

Aspects of the disclosure may be even more critical for implementations of the power module 100 where the pinouts, such as the high side Kelvin terminal 202, the high side gate terminal 302, the low side Kelvin terminal 402, and the low side gate terminal 502, are not arranged symmetrically on the power module 100. Aspects of the disclosure may circumvent this problem of asymmetry when implementing the at least one first position device 101 and/or the at least one second position device 102, such as SiC MOSFET devices, in such implementations of the power module 100. However, the disclosed implementations of the power module 100 also have numerous benefits for symmetrical arrangements of the pinouts.

Typically, routing is implemented with a few different combinations of terminals, aluminum wires, printed-circuit boards (PCBs), Direct Bonded Copper (DBC) substrate traces, Active Metal Brazed (AMB) substrate traces, and/or the like. The high side Kelvin bus bar 200, the high side gate bus bar 300, the low side Kelvin bus bar 400, and/or the low side gate bus bar 500 may replace PCBs, which limit the routing in two-dimensional (2-D) space. In this regard, the disclosed implementations of the high side Kelvin bus bar 200, the high side gate bus bar 300, the low side Kelvin bus bar 400, and/or the low side gate bus bar 500 may allow the three-dimensional (3-D) routing facilitated in aspects to bend portions thereof at multiple locations. A PCB would be an extra component in the bill of materials (BOM) to manage. In contrast, embedding the high side Kelvin bus bar 200, the high side gate bus bar 300, the low side Kelvin bus bar 400, and/or the low side gate bus bar 500 in the housing 110 reduces the BOM. In other words, implementation of the power module 100 with the disclosed implementations of the high side Kelvin bus bar 200, the high side gate bus bar 300, the low side Kelvin bus bar 400, and/or the low side gate bus bar 500 may reduce manufacturing cost, manufacturing complexity, and/or the like.

Aspects of the power module 100 may implement the high side Kelvin bus bar 200, the high side gate bus bar 300, the low side Kelvin bus bar 400, and/or the low side gate bus bar 500 via an optimization of the length, width, spacing, and/or the like, aided by finite-element simulation. Further, aspects of the power module 100 implementing the high side Kelvin bus bar 200, the high side gate bus bar 300, the low side Kelvin bus bar 400, and/or the low side gate bus bar 500 may account for constraints from the housing 110, a process of forming the housing 110, such as co-molding injection process, and industry-standard module footprint and pinouts. The high side Kelvin bus bar 200, the high side gate bus bar 300, the low side Kelvin bus bar 400, and/or the low side gate bus bar 500 may be optimized as taught by the disclosure to concurrently achieve near perfect matching and significantly lower inductances. This results in an approximate 75.3% and 67.5% reduction in HS and LS inductances respectively for some applications.

In aspects, the disclosed implementations may reduce HS inductance 20 to 80%. In aspects, the disclosed implementations may reduce HS inductance more than 20%, more than 30%, more than 40%, more than 50%, more than 60%, or more than 70%. In aspects, the disclosed implementations may reduce LS inductance 20 to 70%. In aspects, the disclosed implementations may reduce LS inductance more than 20%, more than 30%, more than 40%, more than 50%, or more than 60%.

This improvement may result in faster signal propagation from the gate driver to the gates of the at least one first position device 101 and the at least one second position device 102, faster charging of the input capacitance of the at least one first position device 101 and the at least one second position device 102, quicker turn-on of the at least one first position device 101 and the at least one second position device 102, and increases the resonant frequency of the G-SK loops (Gate-Source Kelvin), for example with Ls and input capacitance. At resonance the G-SK loop impedance would be equal to or approach Z=RG.

As further detailed herein, the high side Kelvin bus bar 200, the high side gate bus bar 300, the low side Kelvin bus bar 400, and the low side gate bus bar 500 may be configured and arranged to provide lower inductance. In particular, components of the high side Kelvin bus bar 200, the high side gate bus bar 300, the low side Kelvin bus bar 400, and/or the low side gate bus bar 500 may be optimized including optimizing length, path, width, spacing, and/or the like of components thereof to achieve low inductances for both signal loops.

Moreover, as further detailed herein, the high side Kelvin bus bar 200 and the high side gate bus bar 300 may be configured and arranged to have an equivalent inductance or substantially equivalent (as defined herein) inductance; and the low side Kelvin bus bar 400 and the low side gate bus bar 500 may be configured and arranged to have an equivalent inductance or substantially equivalent inductance.

In aspects, the high side Kelvin bus bar 200, the high side gate bus bar 300, the low side Kelvin bus bar 400, and the low side gate bus bar 500 may be configured and arranged such that a combined inductance of the high side Kelvin bus bar 200 and the high side gate bus bar 300 may be equivalent or substantially equivalent with a combined inductance of the low side Kelvin bus bar 400 and the low side gate bus bar 500. In aspects, the high side Kelvin bus bar 200, the high side gate bus bar 300, the low side Kelvin bus bar 400, and the low side gate bus bar 500 may be configured and arranged such that a combined inductance of the high side Kelvin bus bar 200 and the high side gate bus bar 300 that includes a deduction of mutual inductance may be equivalent or substantially equivalent with a combined inductance of the low side Kelvin bus bar 400 and the low side gate bus bar 500 that includes a deduction of mutual inductance. In this regard, “substantially equivalent” may be defined as less than a 2% difference, less than a 1% difference, or less than a 0.5% difference; and/or “substantially equivalent” may be defined as a 0-2% difference, a 0-1% difference, or a 0.5% difference. In aspects, “matched,” “match,” and/or “matching” may be defined as “substantially equivalent.”

The high side Kelvin bus bar 200 may receive Kelvin signals from the high side Kelvin terminal 202 and provide the Kelvin signals through the high side Kelvin connections 222 and/or the substrate 104 to the at least one first position device 101. Likewise, the high side gate bus bar 300 may receive gate signals from the high side gate terminal 302 and provide the gate signals through the high side gate connections 322 and/or the substrate 104 to the at least one first position device 101. In this regard, the high side Kelvin bus bar 200 and the high side gate bus bar 300 may be configured to form a high side signal loop 122.

Further, the low side Kelvin bus bar 400 may receive Kelvin signals from the low side Kelvin terminal 402 and provide the Kelvin signals through the low side Kelvin connections 422 and/or the substrate 104 to the at least one second position device 102. Likewise, the low side gate bus bar 500 may receive gate signals from the low side gate bus bar 500 and provide the gate signals through the low side gate connections 522 and/or the substrate 104 to the at least one second position device 102. In this regard, the low side Kelvin bus bar 400 and the low side gate bus bar 500 may be configured to form a low side signal loop 121. In particular aspects, the high side Kelvin bus bar 200, the high side gate bus bar 300, the low side Kelvin bus bar 400, and the low side gate bus bar 500, may be structured and arranged within the power module 100 such that an inductance of the low side signal loop 121 and an inductance of the high side signal loop 122 may be equivalent and/or substantially equivalent. In particular aspects, the high side Kelvin bus bar 200, the high side gate bus bar 300, the low side Kelvin bus bar 400, and the low side gate bus bar 500, may be structured and arranged within the power module 100 such that an inductance of the low side signal loop 121 that includes a deduction of mutual inductance and an inductance of the high side signal loop 122 that includes a deduction of mutual inductance may be equivalent and/or substantially equivalent.

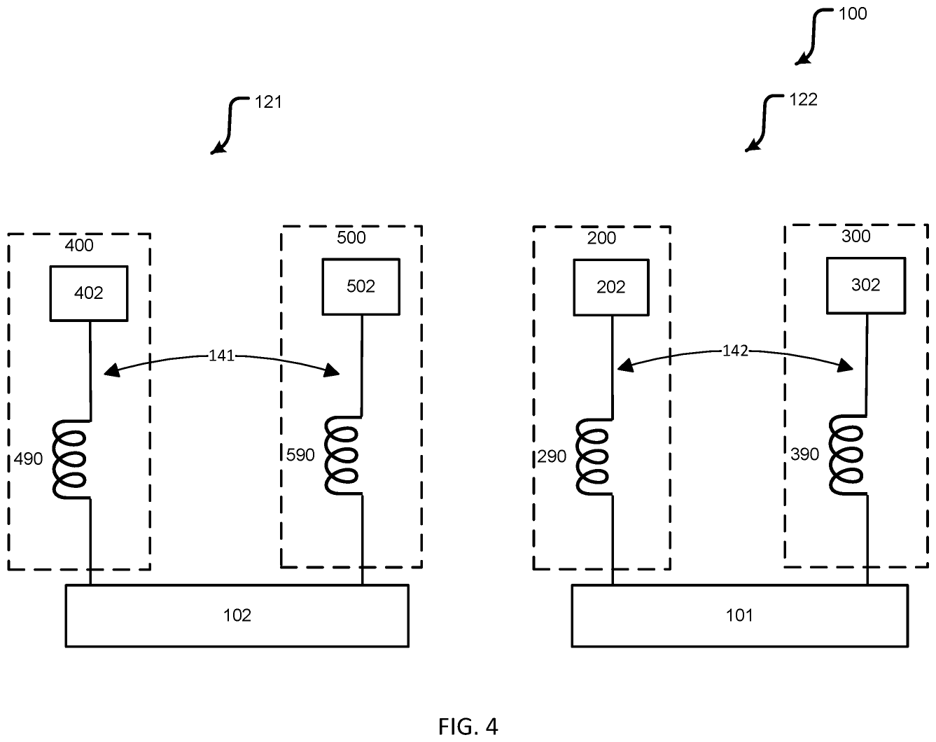

FIG. 4 illustrates a partial equivalent circuit diagram of the power module according to FIG. 2.

In particular, FIG. 4 illustrates a partial equivalent circuit diagram of the power module 100 according to FIG. 2. As illustrated in FIG. 4, the low side Kelvin bus bar 400 may have a low side Kelvin bus bar inductance 490 between the low side Kelvin terminal 402 and the low side Kelvin connections 422 and/or the at least one second position device 102; the low side gate bus bar 500 may have a low side gate bus bar inductance 590 between the low side gate terminal 502 and the low side gate connections 522 and/or the at least one second position device 102; and there may be a low side mutual inductance 141 between the low side Kelvin bus bar 400 and the low side gate bus bar 500. Accordingly, the low side Kelvin bus bar inductance 490 and the low side gate bus bar inductance 590 combined together with a deduction of the low side mutual inductance 141 may be the inductance of the low side signal loop 121. In particular aspects, the low side Kelvin bus bar inductance 490 and the low side gate bus bar inductance 590 combined together with a deduction of the low side mutual inductance 141 from the low side Kelvin bus bar 400 and a deduction of the low side mutual inductance 141 from the low side gate bus bar 500 may be the inductance of the low side signal loop 121.

As illustrated in FIG. 4, the high side Kelvin bus bar 200 may have a high side Kelvin bus bar inductance 290 between the high side Kelvin terminal 202 and the high side Kelvin connections 222 and/or the at least one first position device 101; the high side gate bus bar 300 may have a high side gate bus bar inductance 390 between the high side gate terminal 302 and the high side gate connections 322 and/or the at least one first position device 101; and there may be a high side mutual inductance 142 between the high side Kelvin bus bar 200 and the high side gate bus bar 300. Accordingly, the high side Kelvin bus bar inductance 290 and the high side gate bus bar inductance 390 combined together with a deduction from the high side mutual inductance 142 may be the inductance of the high side signal loop 122. In particular aspects, the high side Kelvin bus bar inductance 290 and the high side gate bus bar inductance 390 combined together with a deduction of the high side mutual inductance 142 from the high side Kelvin bus bar 200 and a deduction of the high side mutual inductance 142 from the high side gate bus bar inductance 390 may be the inductance of the high side signal loop 122.

Additionally, the low side Kelvin bus bar 400 may be configured such that the low side Kelvin bus bar inductance 490 is lower by implementation of various configurations and constructions as described herein; and the low side gate bus bar 500 may be configured such that the low side gate bus bar inductance 590 is lower by implementation of various configurations and constructions as described herein. Moreover, the high side Kelvin bus bar 200 may be configured such that the high side Kelvin bus bar inductance 290 is lower by implementation of various configurations and constructions as described herein; and the high side gate bus bar 300 may be configured such that the high side gate bus bar inductance 390 is lower by implementation of various configurations and constructions as described herein.

Additionally, the low side Kelvin bus bar 400 and the low side gate bus bar 500 may be configured and constructed such that the low side Kelvin bus bar inductance 490 and the low side gate bus bar inductance 590 are equivalent or substantially equivalent; and the high side Kelvin bus bar 200 and the high side gate bus bar 300 may be configured and constructed such that the high side Kelvin bus bar inductance 290 and the high side gate bus bar inductance 390 are equivalent or substantially equivalent.

Additionally, the high side Kelvin bus bar 200, the high side gate bus bar 300, the low side Kelvin bus bar 400, and the low side gate bus bar 500 may be configured and constructed such that the high side Kelvin bus bar inductance 290, the high side gate bus bar inductance 390, the low side Kelvin bus bar inductance 490, and the low side gate bus bar inductance 590 are substantially equivalent.

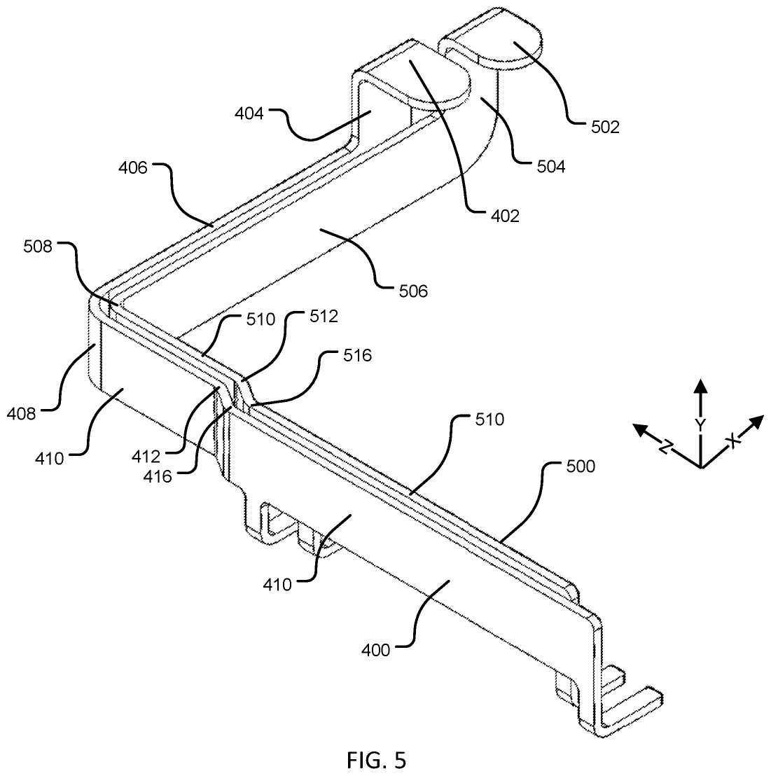

FIG. 5 illustrates a perspective view of the low side Kelvin bus bar and the low side gate bus bar according to aspects of the disclosure.

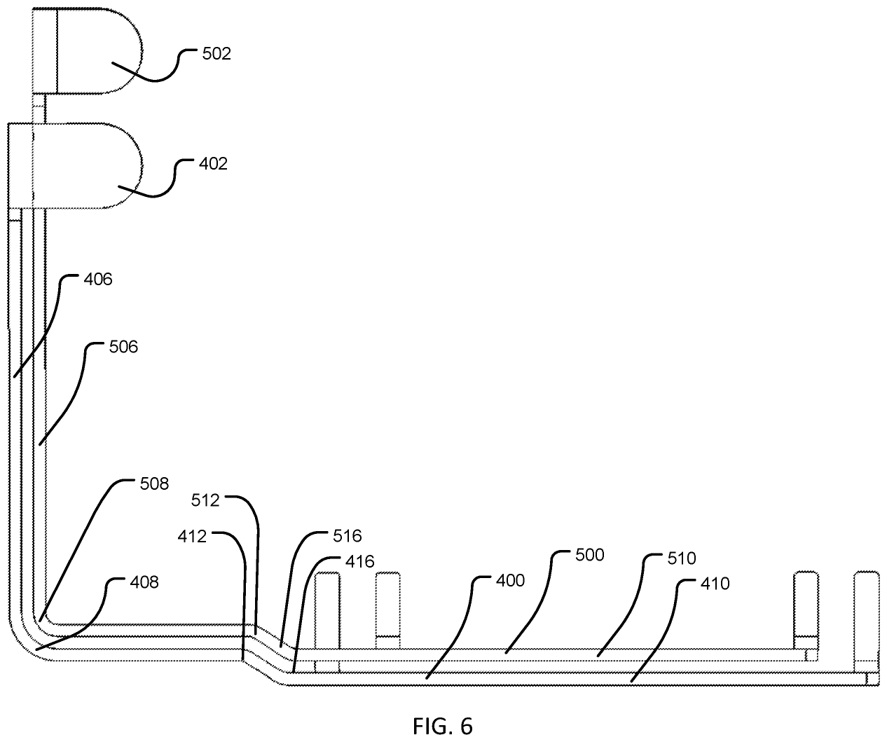

FIG. 6 illustrates a top view of the low side Kelvin bus bar and the low side gate bus bar according to aspects of the disclosure.

In particular, FIG. 5 illustrates perspective views of the low side Kelvin bus bar 400 and the low side gate bus bar 500 according to aspects of the disclosure.

The low side Kelvin bus bar 400 may include a vertical portion 404, a lateral portion 406, a first bend portion 408, a longitudinal portion 410, a second bend portion 412, a third bend portion 416, and/or the like. In aspects, the vertical portion 404 may extend vertically along the y-axis from the low side Kelvin terminal 402 down to the lateral portion 406. In aspects, the lateral portion 406 may extend laterally along the x-axis from the vertical portion 404 to the first bend portion 408. In aspects, the longitudinal portion 410 may extend longitudinally along the z-axis from the first bend portion 408 to the second bend portion 412.

The low side gate bus bar 500 may include a vertical portion 504, a lateral portion 506, a first bend portion 508, a longitudinal portion 510, a second bend portion 512, a third bend portion 516, and/or the like. In aspects, the vertical portion 504 may extend vertically along the y-axis from the low side gate terminal 502 down to the lateral portion 506. In aspects, the lateral portion 506 may extend laterally along the x-axis from the vertical portion 504 to the first bend portion 508. In aspects, the longitudinal portion 510 may extend longitudinally along the z-axis from the first bend portion 508 to the second bend portion 512.

In this regard, a configuration of the low side Kelvin bus bar 400 and the low side gate bus bar 500 as well as arrangement of the low side gate bus bar 500 with respect to the low side Kelvin bus bar 400 may be configured to result in the low side Kelvin bus bar inductance 490, the low side gate bus bar inductance 590 being lower, and mutual inductance between low side gate and low side Kelvin bus bars being higher (the low side mutual inductance 141).

In aspects, the low side gate bus bar 500 and the low side Kelvin bus bar 400 may be configured, structured, and/or arranged with a uniform horizontal gap therebetween may lower the low side Kelvin bus bar inductance 490 and the low side gate bus bar inductance 590 and increase the mutual inductance between low side gate and Kelvin bus bars (the low side mutual inductance 141). In aspects, arranging the low side gate bus bar 500 and the low side Kelvin bus bar 400 with a uniform horizontal gap therebetween may lower the low side Kelvin bus bar inductance 490 and the low side gate bus bar inductance 590 and increase the mutual inductance between low side gate and Kelvin bus bars (the low side mutual inductance 141).

In aspects, one or more upper surfaces of the low side Kelvin bus bar 400 and the low side gate bus bar 500 may be configured, structured, and/or arranged within the same plane, such as the ZX plane as illustrated, may lower the low side Kelvin bus bar inductance 490 and the low side gate bus bar inductance 590. In aspects, arranging one or more upper surfaces of the low side Kelvin bus bar 400 and the low side gate bus bar 500 within the same plane, such as the ZX plane as illustrated, may lower the low side Kelvin bus bar inductance 490 and the low side gate bus bar inductance 590.

In aspects, one or more lower surfaces of the low side Kelvin bus bar 400 and the low side gate bus bar 500 may be configured, structured, and/or arranged within the same plane, such as the ZX plane as illustrated, may lower the low side Kelvin bus bar inductance 490 and the low side gate bus bar inductance 590. In aspects, arranging one or more lower surfaces of the low side Kelvin bus bar 400 and the low side gate bus bar 500 within the same plane, such as the ZX plane as illustrated, may lower the low side Kelvin bus bar inductance 490 and the low side gate bus bar inductance 590.

In aspects, a portion of the vertical portion 404 adjacent along the z-axis to a portion of the lateral portion 506 may be configured, structured, and/or arranged with a uniform horizontal gap therebetween may lower the low side Kelvin bus bar inductance 490 and the low side gate bus bar inductance 590 and increase the mutual inductance between low side gate and Kelvin bus bars (the low side mutual inductance 141). In aspects, arranging a portion of the vertical portion 404 adjacent along the z-axis to a portion of the lateral portion 506 with a uniform horizontal gap therebetween may lower the low side Kelvin bus bar inductance 490 and the low side gate bus bar inductance 590 and increase the mutual inductance between low side gate and Kelvin bus bars (the low side mutual inductance 141).

In aspects, the lateral portion 506 and the lateral portion 406 may be configured, structured, and/or arranged with a uniform horizontal gap therebetween may lower the low side Kelvin bus bar inductance 490 and the low side gate bus bar inductance 590. In aspects, arranging the lateral portion 506 and the lateral portion 406 with a uniform horizontal gap therebetween may lower the low side Kelvin bus bar inductance 490 and the low side gate bus bar inductance 590 and increase the mutual inductance between low side gate and Kelvin bus bars (the low side mutual inductance 141).

In aspects, upper surfaces of the lateral portion 406 and the lateral portion 506 may be configured, structured, and/or arranged within a same plane, the ZX plane as illustrated, may lower the low side Kelvin bus bar inductance 490 and the low side gate bus bar inductance 590 and increase the mutual inductance between low side gate and Kelvin bus bars (the low side mutual inductance 141). In aspects, arranging upper surfaces of the lateral portion 406 and the lateral portion 506 within a same plane, the ZX plane as illustrated, may lower the low side Kelvin bus bar inductance 490 and the low side gate bus bar inductance 590 and increase the mutual inductance between low side gate and Kelvin bus bars (the low side mutual inductance 141).

In aspects, lower surfaces of the lateral portion 406 and the lateral portion 506 may be configured, structured, and/or arranged within a same plane, the ZX plane as illustrated, may lower the low side Kelvin bus bar inductance 490 and the low side gate bus bar inductance 590 and increase the mutual inductance between low side gate and Kelvin bus bars (the low side mutual inductance 141). In aspects, arranging lower surfaces of the lateral portion 406 and the lateral portion 506 within a same plane, the ZX plane as illustrated, may lower the low side Kelvin bus bar inductance 490 and the low side gate bus bar inductance 590 and increase the mutual inductance between low side gate and Kelvin bus bars (the low side mutual inductance 141).

In aspects, the first bend portion 508 and the first bend portion 408 may be configured, structured, and/or arranged with a uniform horizontal gap therebetween may lower the low side Kelvin bus bar inductance 490 and the low side gate bus bar inductance 590 and increase the mutual inductance between low side gate and Kelvin bus bars (the low side mutual inductance 141). In aspects, arranging the first bend portion 508 and the first bend portion 408 with a uniform horizontal gap therebetween may lower the low side Kelvin bus bar inductance 490 and the low side gate bus bar inductance 590 and increase the mutual inductance between low side gate and Kelvin bus bars (the low side mutual inductance 141).

In aspects, upper surfaces of the first bend portion 408 and the first bend portion 508 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging upper surfaces of the first bend portion 408 and the first bend portion 508 within the ZX plane may lower the low side Kelvin bus bar inductance 490 and the low side gate bus bar inductance 590 and increase the mutual inductance between low side gate and Kelvin bus bars (the low side mutual inductance 141).

In aspects, lower surfaces of the first bend portion 408 and the first bend portion 508 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging lower surfaces of the first bend portion 408 and the first bend portion 508 within the ZX plane may lower the low side Kelvin bus bar inductance 490 and the low side gate bus bar inductance 590 and increase the mutual inductance between low side gate and Kelvin bus bars (the low side mutual inductance 141).

In aspects, upper surfaces of the second bend portion 412 and the second bend portion 512 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging upper surfaces of the second bend portion 412 and the second bend portion 512 within the ZX plane may lower the low side Kelvin bus bar inductance 490 and the low side gate bus bar inductance 590 and increase the mutual inductance between low side gate and Kelvin bus bars (the low side mutual inductance 141).

In aspects, lower surfaces of the second bend portion 412 and the second bend portion 512 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging lower surfaces of the second bend portion 412 and the second bend portion 512 within the ZX plane may lower the low side Kelvin bus bar inductance 490 and the low side gate bus bar inductance 590 and increase the mutual inductance between low side gate and Kelvin bus bars (the low side mutual inductance 141).

In aspects, the longitudinal portion 510 and the longitudinal portion 410 may be configured, structured, and/or arranged with a uniform horizontal gap therebetween may lower the low side Kelvin bus bar inductance 490 and the low side gate bus bar inductance 590 and increase the mutual inductance between low side gate and Kelvin bus bars. In aspects, arranging the longitudinal portion 510 and the longitudinal portion 410 with a uniform horizontal gap therebetween may lower the low side Kelvin bus bar inductance 490 and the low side gate bus bar inductance 590 and increase the mutual inductance between low side gate and Kelvin bus bars (the low side mutual inductance 141).

In aspects, upper surfaces of the longitudinal portion 410 and the longitudinal portion 510 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging upper surfaces of the longitudinal portion 410 and the longitudinal portion 510 within the ZX plane may lower the low side Kelvin bus bar inductance 490 and the low side gate bus bar inductance 590 and increase the mutual inductance between low side gate and Kelvin bus bars (the low side mutual inductance 141).

In aspects, lower surfaces of the longitudinal portion 410 and the longitudinal portion 510 may be configured, structured, and/or arranged within the ZX plane may lower the low side Kelvin bus bar inductance 490 and the low side gate bus bar inductance 590 and increase the mutual inductance between low side gate and Kelvin bus bars (the low side mutual inductance 141). In aspects, arranging lower surfaces of the longitudinal portion 410 and the longitudinal portion 510 within the ZX plane may lower the low side Kelvin bus bar inductance 490 and the low side gate bus bar inductance 590 and increase the mutual inductance between low side gate and Kelvin bus bars (the low side mutual inductance 141).

In aspects, configuring the low side Kelvin bus bar 400 and the low side gate bus bar 500 such that the number of bends and/or bent portions are equivalent may lower the low side Kelvin bus bar inductance 490 and the low side gate bus bar inductance 590 and increase the mutual inductance between low side gate and Kelvin bus bars (the low side mutual inductance 141).

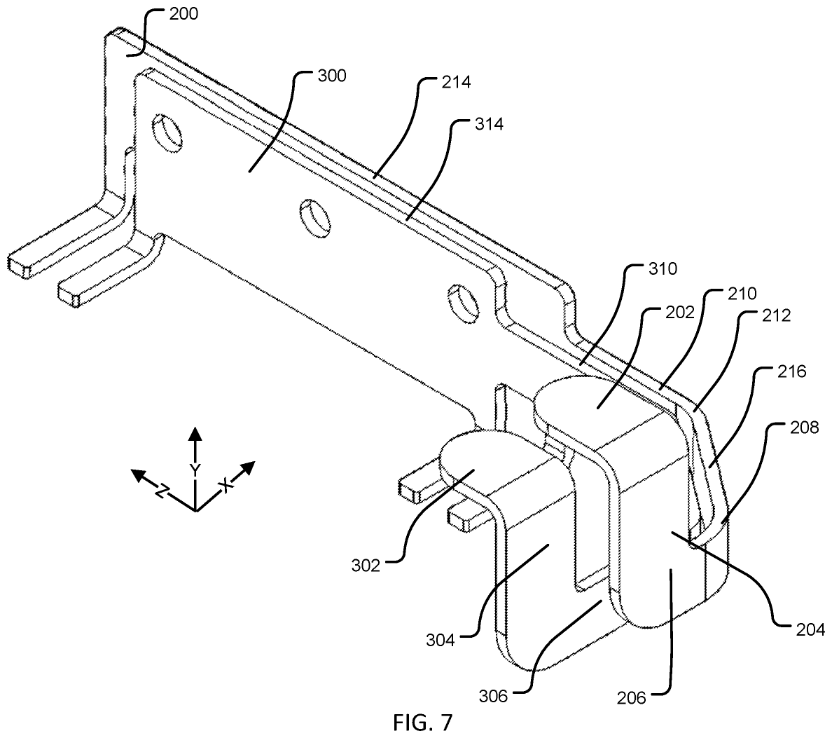

FIG. 7 illustrates a partial perspective view of the high side Kelvin bus bar and the high side gate bus bar according to aspects of the disclosure.

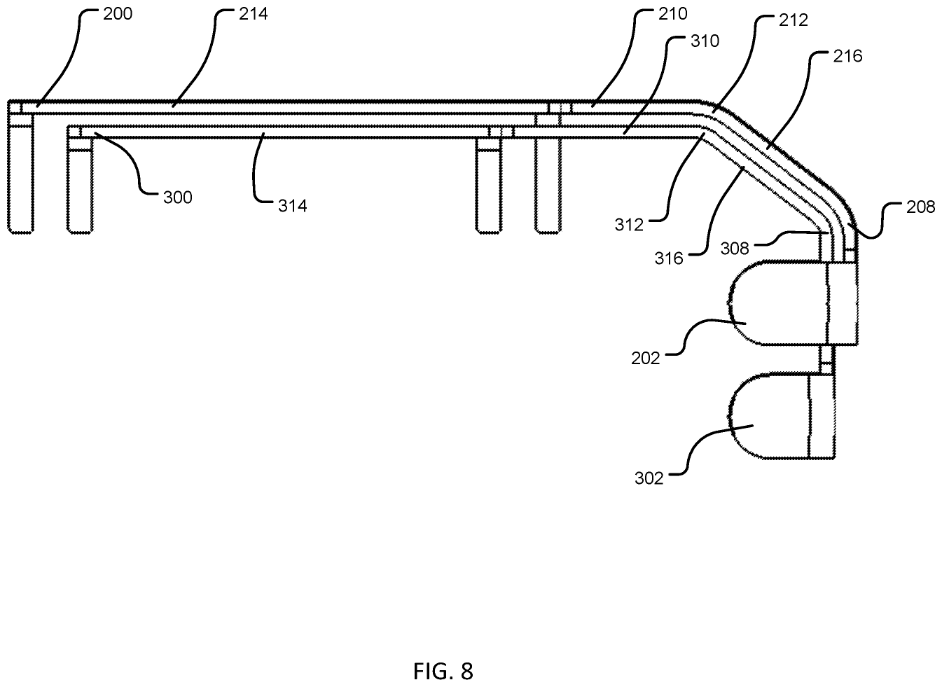

FIG. 8 illustrates a partial top view of the high side Kelvin bus bar and the high side gate bus bar according to FIG. 7.

In particular, FIG. 7 illustrates a partial perspective view of the high side Kelvin bus bar 200 and the high side gate bus bar 300 according to aspects of the disclosure. The high side Kelvin bus bar 200 may include a vertical portion 204, a lateral portion 206, a first bend portion 208, diagonal portion 216, a second bend portion 212, a first longitudinal portion 210, a second longitudinal portion 214, and/or the like. In aspects, the vertical portion 204 may extend vertically along the y-axis from the high side Kelvin terminal 202 down to the lateral portion 206. In aspects, the lateral portion 206 may extend laterally along the x-axis from the vertical portion 204 to the first bend portion 208. In aspects, the diagonal portion 216 may extend laterally between the first bend portion 208 and the second bend portion 212. In aspects, the first longitudinal portion 210 may extend longitudinally along the z-axis from the second bend portion 212 to the second longitudinal portion 214. In aspects, the second longitudinal portion 214 may extend longitudinally along the z-axis from the first longitudinal portion 210.

The high side gate bus bar 300 may include a vertical portion 304, a lateral portion 306, a first bend portion 308, diagonal portion 316, a second bend portion 312, a first longitudinal portion 310, a second longitudinal portion 314, and/or the like. In aspects, the vertical portion 304 may extend vertically along the y-axis from the high side gate terminal 302 down to the diagonal portion 316. In aspects, the lateral portion 306 may extend laterally along the x-axis from the vertical portion 304 to the first bend portion 308. In aspects, the diagonal portion 316 may extend laterally between the first bend portion 308 and the second bend portion 312. In aspects, the first longitudinal portion 310 may extend longitudinally along the z-axis from the first bend portion 308 to the second longitudinal portion 314. In aspects, the second longitudinal portion 314 may extend longitudinally along the z-axis from the first longitudinal portion 310.

In this regard, a configuration of the high side Kelvin bus bar 200 and the high side gate bus bar 300 as well as arrangement of the high side gate bus bar 300 with respect to the high side Kelvin bus bar 200 may be configured to result in the high side gate bus bar inductance 390 and the high side Kelvin bus bar inductance 290 being lower and the mutual inductance between high side gate and high side Kelvin bus bars being higher (the high side mutual inductance 142).

In aspects, the high side gate bus bar 300 and the high side Kelvin bus bar 200 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the high side gate bus bar 300 and the high side Kelvin bus bar 200 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, one or more upper surfaces of the high side Kelvin bus bar 200 and the high side gate bus bar 300 may be configured, structured, and/or arranged within the ZX plane may lower the high side gate bus bar inductance 390 and the high side Kelvin bus bar inductance 290 and increase the mutual inductance between high side gate and high side Kelvin bus bars (the high side mutual inductance 142). In aspects, arranging one or more upper surfaces of the high side Kelvin bus bar 200 and the high side gate bus bar 300 within the ZX plane may lower the high side gate bus bar inductance 390 and the high side Kelvin bus bar inductance 290 and increase the mutual inductance between high side gate and high side Kelvin bus bars (the high side mutual inductance 142).

In aspects, one or more lower surfaces of the high side Kelvin bus bar 200 and the high side gate bus bar 300 may be configured, structured, and/or arranged within the ZX plane may lower the high side gate bus bar inductance 390 and the high side Kelvin bus bar inductance 290 and increase the mutual inductance between high side gate and high side Kelvin bus bars (the high side mutual inductance 142). In aspects, arranging one or more lower surfaces of the high side Kelvin bus bar 200 and the high side gate bus bar 300 within the ZX plane may lower the high side gate bus bar inductance 390 and the high side Kelvin bus bar inductance 290 and increase the mutual inductance between high side gate and high side Kelvin bus bars (the high side mutual inductance 142).

In aspects, a portion of the vertical portion 204 adjacent may be configured, structured, and/or arranged with a gap therebetween along a horizontal axis or the z-axis to a portion of the lateral portion 306 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging a portion of the vertical portion 204 adjacent with a gap therebetween along a horizontal axis or the z-axis to a portion of the lateral portion 306 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, the lateral portion 306 and the lateral portion 206 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the lateral portion 306 and the lateral portion 206 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, upper surfaces of the lateral portion 206 and the lateral portion 306 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging upper surfaces of the lateral portion 206 and the lateral portion 306 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, lower surfaces of the lateral portion 206 and the lateral portion 306 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging lower surfaces of the lateral portion 206 and the lateral portion 306 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, the first bend portion 308 and the first bend portion 208 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the first bend portion 308 and the first bend portion 208 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, upper surfaces of the first bend portion 208 and the first bend portion 308 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging upper surfaces of the first bend portion 208 and the first bend portion 308 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, lower surfaces of the first bend portion 208 and the first bend portion 308 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging lower surfaces of the first bend portion 208 and the first bend portion 308 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, the diagonal portion 316 and the diagonal portion 216 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the diagonal portion 316 and the diagonal portion 216 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, upper surfaces of the diagonal portion 216 and the diagonal portion 316 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging upper surfaces of the diagonal portion 216 and the diagonal portion 316 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, lower surfaces of the diagonal portion 216 and the diagonal portion 316 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging lower surfaces of the diagonal portion 216 and the diagonal portion 316 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, the second bend portion 312 and the second bend portion 212 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the second bend portion 312 and the second bend portion 212 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, upper surfaces of the second bend portion 212 and the second bend portion 312 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging upper surfaces of the second bend portion 212 and the second bend portion 312 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, lower surfaces of the second bend portion 212 and the second bend portion 312 may be configured, structured, and/or arranged within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging lower surfaces of the second bend portion 212 and the second bend portion 312 within the same horizontal plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, the first longitudinal portion 310 and the first longitudinal portion 210 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the first longitudinal portion 310 and the first longitudinal portion 210 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, upper surfaces of the first longitudinal portion 210 and the first longitudinal portion 310 may be configured, structured, and/or arranged within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging upper surfaces of the first longitudinal portion 210 and the first longitudinal portion 310 within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, lower surfaces of the first longitudinal portion 210 and the first longitudinal portion 310 may be configured, structured, and/or arranged within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging lower surfaces of the first longitudinal portion 210 and the first longitudinal portion 310 within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, the second longitudinal portion 214 and the second longitudinal portion 314 may be configured, structured, and/or arranged with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142). In aspects, arranging the second longitudinal portion 214 and the second longitudinal portion 314 with a uniform horizontal gap therebetween may lower the high side gate bus bar inductance 390 and the high side Kelvin bus bar inductance 290 and increase the mutual inductance between high side gate and high side Kelvin bus bars (the high side mutual inductance 142).

In aspects, a majority of the upper surfaces of the second longitudinal portion 214 and the second longitudinal portion 314 may be configured, structured, and/or arranged within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging a majority of the upper surfaces of the second longitudinal portion 214 and the second longitudinal portion 314 within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, a majority of the lower surfaces of the second longitudinal portion 214 and the second longitudinal portion 314 may be configured, structured, and/or arranged within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142). In aspects, arranging a majority of the lower surfaces of the second longitudinal portion 214 and the second longitudinal portion 314 within the same plane, such as the ZX plane as illustrated, may lower the high side gate bus bar inductance 390 and the high side Kelvin bus bar inductance 290 and increase the mutual inductance between high side gate and high side Kelvin bus bars (the high side mutual inductance 142).

In aspects, configuring the high side Kelvin bus bar 200 and the high side gate bus bar 300 such that the number of bends and/or bent portions are equivalent may lower the high side gate bus bar inductance 390 and the high side Kelvin bus bar inductance 290 and increase the mutual inductance between high side gate and high side Kelvin bus bars (the high side mutual inductance 142).

As previously noted, the high side Kelvin bus bar 200, the high side gate bus bar 300, the low side Kelvin bus bar 400, and the low side gate bus bar 500 may be configured and constructed such that the high side Kelvin bus bar inductance 290, the high side gate bus bar inductance 390, the low side Kelvin bus bar inductance 490, and the low side gate bus bar inductance 590 are substantially equivalent. In this regard, one or more portions of one or more of the high side Kelvin bus bar 200, the high side gate bus bar 300, the low side Kelvin bus bar 400, and/or the low side gate bus bar 500 may be modified to compensate for inductance. More specifically, in order for the high side Kelvin bus bar 200, the high side gate bus bar 300, the low side Kelvin bus bar 400, and the low side gate bus bar 500 to have a substantially equivalent inductance, a portion of these structures may be modified to ensure such substantially equivalent inductance.

In one aspect, the high side gate bus bar 300 may be modified to implement the second longitudinal portion 314 as illustrated in FIG. 7 to adjust the high side gate bus bar inductance 390 of the high side gate bus bar 300. Accordingly, the second longitudinal portion 314 may be implemented as an inductance adjustment device, the second longitudinal portion 314 may be configured to modify inductance of the high side gate bus bar 300, and/or the like. In this regard, the second longitudinal portion 314 may be configured and arranged to have a vertical height along the y-axis and horizontal width along the z-axis to adjust the high side gate bus bar inductance 390 of the high side gate bus bar 300. In particular aspects, the vertical height along the y-axis of the second longitudinal portion 314 may be greater than a height of one or more other components of the high side gate bus bar 300. In particular aspects, the vertical height along the y-axis of the second longitudinal portion 314 may be greater than a height of the first longitudinal portion 310, the lateral portion 306, the first bend portion 308, the second bend portion 312, and/or the like.

In one aspect, the high side Kelvin bus bar 200 may be modified to implement the second longitudinal portion 214 as illustrated in FIG. 7 to adjust the high side Kelvin bus bar inductance 290 of the high side Kelvin bus bar 200. Accordingly, the second longitudinal portion 214 may be implemented as an inductance adjustment device, the second longitudinal portion 214 may be configured to modify inductance of the high side Kelvin bus bar 200, and/or the like. In this regard, the second longitudinal portion 214 may be configured and arranged to have a vertical height along the y-axis and horizontal width along the z-axis to adjust the high side Kelvin bus bar inductance 290 of the high side Kelvin bus bar 200. In particular aspects, the vertical height along the y-axis of the second longitudinal portion 214 may be greater than a height of one or more other components of the high side Kelvin bus bar 200. In particular aspects, the vertical height along the y-axis of the second longitudinal portion 214 may be greater than a height of the first longitudinal portion 210, the lateral portion 206, the first bend portion 208, the second bend portion 212, and/or the like.

Substantially equivalent being defined as being within 0-10%, 0-6%, 0-2%, or 0-1%. Moreover, substantially equivalent may be defined as being less than 10% different, less than 6% different, less than 2% different, or less than 1% different.

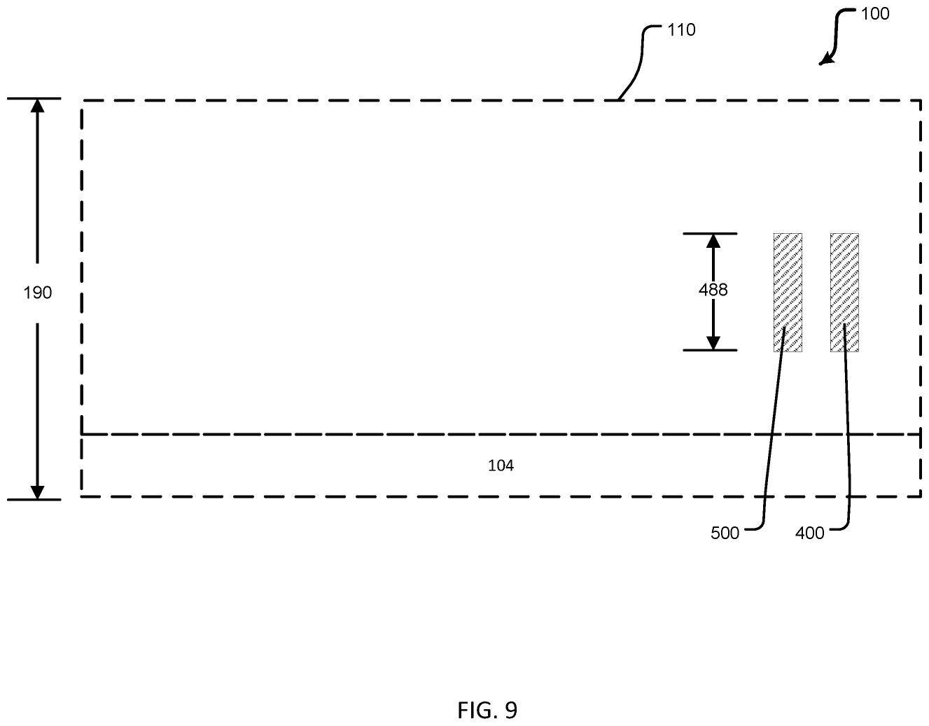

FIG. 9 illustrates a cross-sectional side view of the low side Kelvin bus bar and the low side gate bus bar according to aspects of the disclosure.

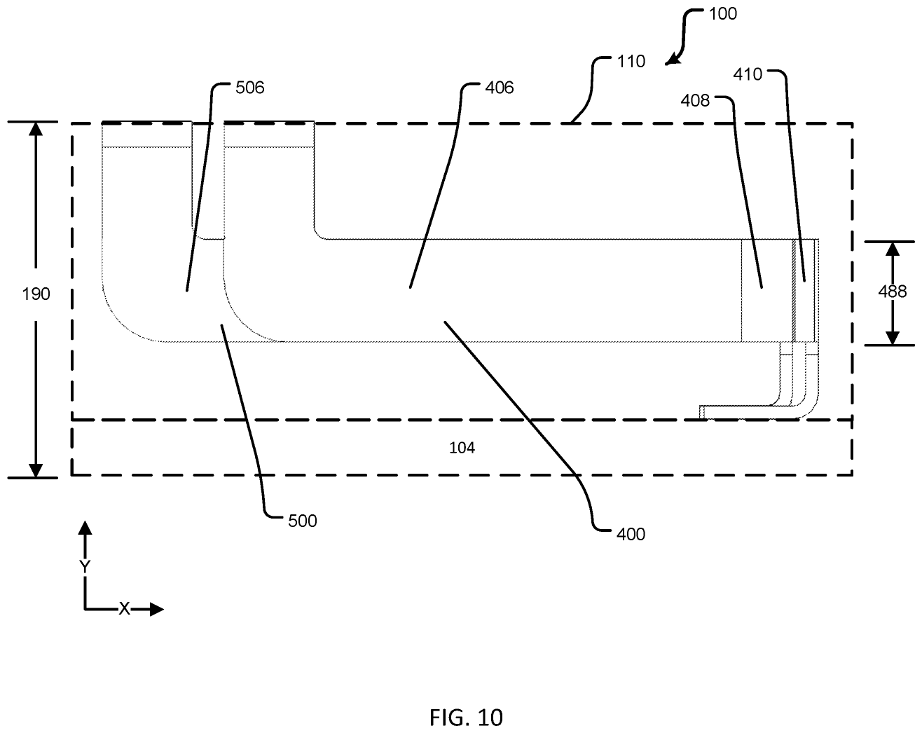

FIG. 10 illustrates a side view of the low side Kelvin bus bar and the low side gate bus bar according to aspects of the disclosure.

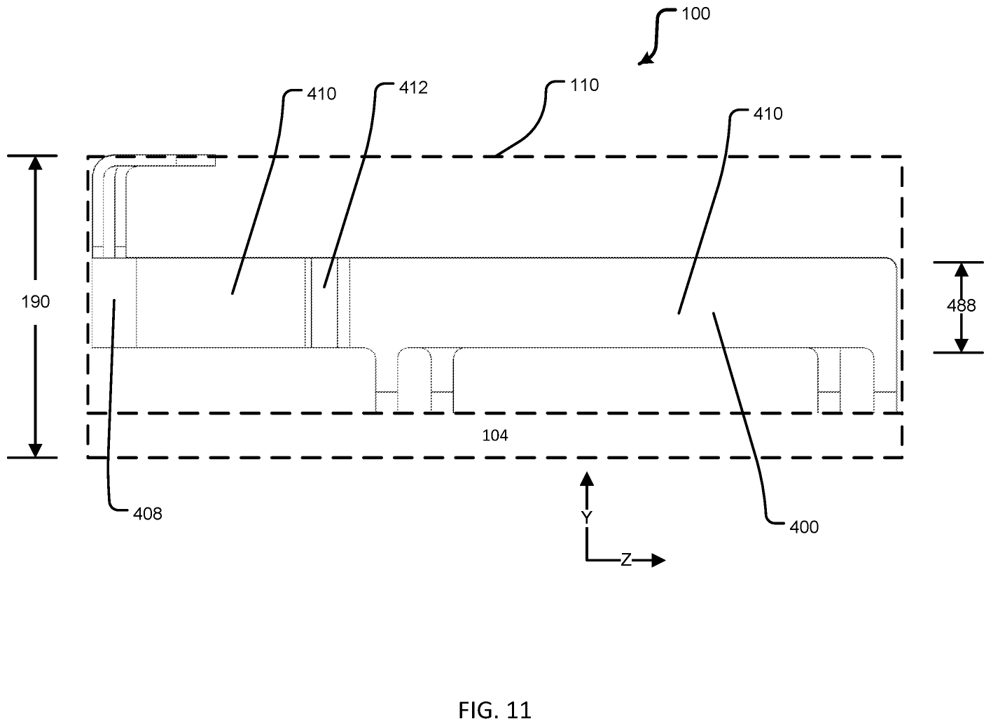

FIG. 11 illustrates another side view of the low side Kelvin bus bar and the low side gate bus bar according to aspects of the disclosure.

In particular, FIG. 9, FIG. 10, and FIG. 11 illustrate views of the low side Kelvin bus bar 400 and the low side gate bus bar 500 according to aspects of the disclosure.

In this regard, a configuration of the low side Kelvin bus bar 400 and the low side gate bus bar 500 may be configured to result in the low side Kelvin bus bar inductance 490 and the low side gate bus bar inductance 590 being lower, and the mutual inductance between low side gate and low side Kelvin bus bars being higher (the low side mutual inductance 141). In this regard, a vertical dimension, which may be a long the y-axis as illustrated, of portions of the low side Kelvin bus bar 400 and the low side gate bus bar 500 may consume a large percentage of the vertical height of the power module 100. With reference to FIGS. 9-11, a vertical height of the power module 100 that includes the substrate 104 and the housing 110 is illustrated as a power module vertical height 190. Additionally, a vertical dimension of particular portions of the low side Kelvin bus bar 400 and the low side gate bus bar 500 is illustrated as a low side bus bar vertical dimension 488.

In this regard, the low side bus bar vertical dimension 488 may be a vertical dimension of various components of the low side Kelvin bus bar 400 and/or the low side gate bus bar 500. For example, the low side bus bar vertical dimension 488 may be a vertical dimension of the lateral portion 506, the lateral portion 406, the first bend portion 408, the longitudinal portion 410, as well as other components of the low side Kelvin bus bar 400 and/or the low side gate bus bar 500. In this regard, the low side bus bar vertical dimension 488 may be 20-60%, 20-30%, 30-40%, 40-50%, or 50%-60%, of the power module vertical height 190. Further, the low side bus bar vertical dimension 488 may be more than 20%, 30%, 40%, or 50% of the power module vertical height 190.

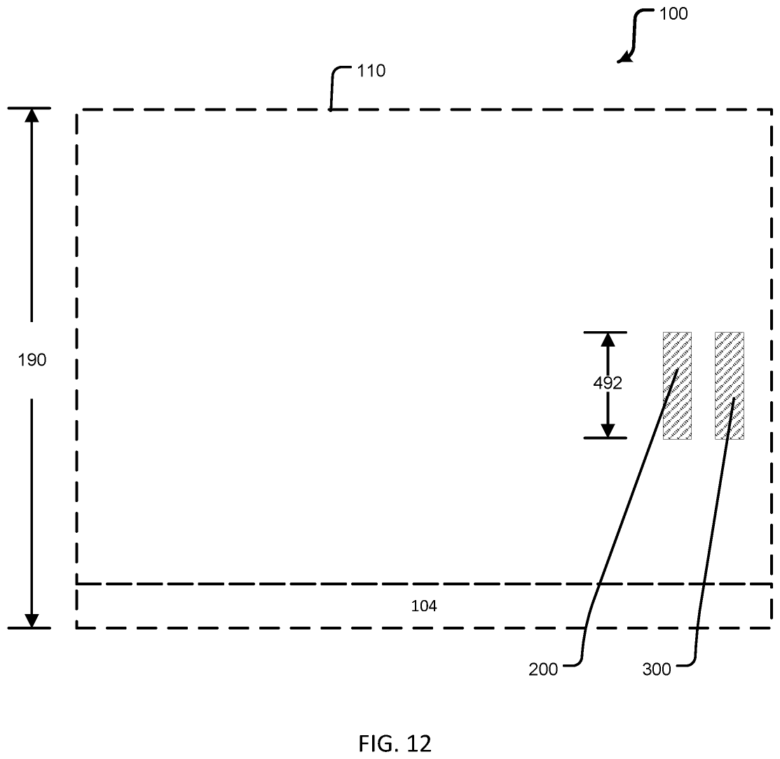

FIG. 12 illustrates a cross-sectional side view of the high side Kelvin bus bar and the high side gate bus bar according to aspects of the disclosure.

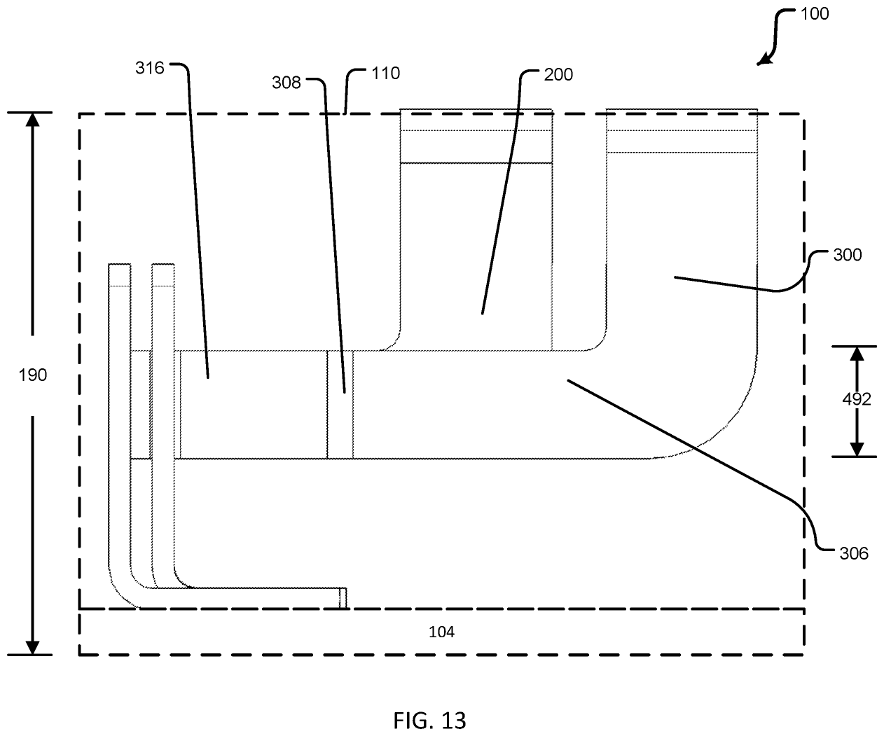

FIG. 13 illustrates a side view of the high side Kelvin bus bar and the high side gate bus bar according to aspects of the disclosure.

In particular, FIG. 12 and FIG. 13 illustrates the use of the high side Kelvin bus bar 200 and the high side gate bus bar 300 according to aspects of the disclosure.

In this regard, a configuration of the high side Kelvin bus bar 200 and the high side gate bus bar 300 may be configured to result in the high side Kelvin bus bar inductance 290 and the high side gate bus bar inductance 390 being lower. In this regard, a vertical dimension, which may be a long the y-axis as illustrated, of portions of the high side Kelvin bus bar 200 and the high side gate bus bar 300 may consume a large percentage of the vertical height of the power module 100. With reference to FIGS. 12 and 13, a vertical height of the power module 100 that includes the substrate 104 and the housing 110 is illustrated as a power module vertical height 190. Additionally, a vertical dimension of particular portions of the high side Kelvin bus bar 200 and the high side gate bus bar 300 is illustrated as a high side bus bar vertical dimension 492.

In this regard, the high side bus bar vertical dimension 492 may be a vertical dimension of various components of the high side Kelvin bus bar 200 and/or the high side gate bus bar 300. For example, the high side bus bar vertical dimension 492 may be a vertical dimension of the diagonal portion 316, the first bend portion 308, the lateral portion 306, as well as other components of the high side Kelvin bus bar 200 and/or the high side gate bus bar 300. In this regard, the high side bus bar vertical dimension 492 may be 20-60%, 20-30%, 30-40%, 40-50%, or 50%-60% of the power module vertical height 190. Further, the high side bus bar vertical dimension 492 may be more than 20%, 30%, 40%, or 50% of the power module vertical height 190.

In one or more aspects, the high side Kelvin bus bar 200, the high side gate bus bar 300, the low side Kelvin bus bar 400, and/or the low side gate bus bar 500 may comprise a metallic material such as copper, gold, nickel, palladium, silver, and the like, and combinations thereof. In aspects, the high side Kelvin bus bar 200, the high side gate bus bar 300, the low side Kelvin bus bar 400, and/or the low side gate bus bar 500 may be formed by one or more of extrusion, die forming, stamping, cutting, indenting, and/or the like. In aspects, the high side Kelvin bus bar 200, the high side gate bus bar 300, the low side Kelvin bus bar 400, and/or the low side gate bus bar 500 may be attached to the substrate 104 with a component attach that may include implementations of adhesive, soldering, sintering, eutectic bonding, ultrasonically welding, and/or the like as described herein. In aspects, the high side Kelvin connections 222 of the high side Kelvin bus bar 200, the high side gate connections 322 of the high side gate bus bar 300, the low side Kelvin connections 422 of the low side Kelvin bus bar 400, and/or the low side gate connections 522 of the low side gate bus bar 500 may be attached to the substrate 104 with a component attach that may include implementations of adhesive, soldering, sintering, eutectic bonding, ultrasonically welding, and/or the like as described herein.

As described herein, aspects, configurations, arrangements, implementations, structures, and/or the like of the high side Kelvin bus bar 200 and the high side gate bus bar 300 may reduce an inductance of the high side signal loop 122. In aspects, configurations, arrangements, implementations, structures, and/or the like of the high side Kelvin bus bar 200 and the high side gate bus bar 300 may result in an inductance of the high side signal loop 122 that may be low. In aspects, configurations, arrangements, implementations, structures, and/or the like of the high side Kelvin bus bar 200 and the high side gate bus bar 300 may result in an inductance of the high side signal loop 122 that is less than 40 nH, 30 nH, 20 nH, 15 nH, or 10 nH. In aspects, configurations, arrangements, implementations, structures, and/or the like of the high side Kelvin bus bar 200 and the high side gate bus bar 300 may result in an inductance of the high side signal loop 122 that may be 5 nH-40 nH, 5 nH-15 nH, 10 nH-20 nH, 20 nH-30 nH, or 30 nH-40 nH.

In aspects described herein, configurations, arrangements, implementations, structures, and/or the like of the high side Kelvin bus bar 200 and the high side gate bus bar 300 may reduce an inductance of the high side signal loop 122 at least 20%, 30%, 40%, 50%, 60%, or 70%. In aspects described herein, configurations, arrangements, implementations, structures, and/or the like of the high side Kelvin bus bar 200 and the high side gate bus bar 300 may reduce an inductance of the high side signal loop 122 at least 20%, 30%, 40%, 50%, 60%, or 70% in comparison to prior art bus bars. In aspects described herein, configurations, arrangements, implementations, structures, and/or the like of the high side Kelvin bus bar 200 and the high side gate bus bar 300 may reduce an inductance of the high side signal loop 122 by 20%-80%, 20%-30%, 30%-40%, 40%-50%, 50%-60%, 60%-70%, or 70%-80%. In aspects described herein, configurations, arrangements, implementations, structures, and/or the like of the high side Kelvin bus bar 200 and the high side gate bus bar 300 may reduce an inductance of the high side signal loop 122 by 20%-80%, 20%-30%, 30%-40%, 40%-50%, 50%-60%, 60%-70%, or 70%-80% in comparison to prior art bus bars.

As described herein, aspects, configurations, arrangements, implementations, structures, and/or the like of the low side Kelvin bus bar 400 and the low side gate bus bar 500 may reduce an inductance of the low side signal loop 121. In aspects, configurations, arrangements, implementations, structures, and/or the like of the low side Kelvin bus bar 400 and the low side gate bus bar 500 may result in an inductance of the low side signal loop 121 that may be low. In aspects, configurations, arrangements, implementations, structures, and/or the like of the low side Kelvin bus bar 400 and the low side gate bus bar 500 may result in an inductance of the low side signal loop 121 that is less than 40 nH, 30 nH, 20 nH, 15 nH, or 10 nH. In aspects, configurations, arrangements, implementations, structures, and/or the like of the low side Kelvin bus bar 400 and the low side gate bus bar 500 may result in an inductance of the low side signal loop 121 that may be 5 nH-40 nH, 5 nH-15 nH, 10 nH-20 nH, 20 nH-30 nH, or 30 nH-40 nH.

In aspects described herein, configurations, arrangements, implementations, structures, and/or the like of the low side Kelvin bus bar 400 and the low side gate bus bar 500 may reduce an inductance of the low side signal loop 121 at least 20%, 30%, 40%, 50%, 60%, or 70%. In aspects described herein, configurations, arrangements, implementations, structures, and/or the like of the low side Kelvin bus bar 400 and the low side gate bus bar 500 may reduce an inductance of the low side signal loop 121 at least 20%, 30%, 40%, 50%, 60%, or 70% in comparison to prior art bus bars. In aspects described herein, configurations, arrangements, implementations, structures, and/or the like of the low side Kelvin bus bar 400 and the low side gate bus bar 500 may reduce an inductance of the low side signal loop 121 by 20%-80%, 20%-30%, 30%-40%, 40%-50%, 50%-60%, 60%-70%, or 70%-80%. In aspects described herein, configurations, arrangements, implementations, structures, and/or the like of the low side Kelvin bus bar 400 and the low side gate bus bar 500 may reduce an inductance of the low side signal loop 121 by 20%-80%, 20%-30%, 30%-40%, 40%-50%, 50%-60%, 60%-70%, or 70%-80% in comparison to prior art bus bars.

In one or more aspects, the housing 110 may comprise a molding compound that may substantially surround the parts of the power module 100 and may be formed of a plastic or a plastic polymer compound, which may be co-molded and/or an injection molded around the parts of the power module 100, thereby providing protection from the outside environment. The molding compound may be formed of a plastic, a mold compound, a plastic compound, a polymer, a polymer compound, a plastic polymer compound, an epoxy molding compound, and/or the like. The molding compound may be co-molded, injection molded, transfer molded, compression molded, and/or the like around the parts of the power module 100, from the outside environment.

In aspects, a molding compound of the housing 110 may flow into the gaps between the high side Kelvin bus bar 200 and the high side gate bus bar 300. In aspects, a molding compound of the housing 110 may flow into the gaps between the low side Kelvin bus bar 400 and the low side gate bus bar 500. In aspects, a molding compound of the housing 110 may flow into other portions of the high side Kelvin bus bar 200, the high side gate bus bar 300, the low side Kelvin bus bar 400, and/or the low side gate bus bar 500. For example, a molding compound of the housing 110 may flow apertures of the high side gate bus bar 300 as illustrated in FIG. 7.

In aspects, a dielectric material may be arranged in the gaps between the high side Kelvin bus bar 200 and the high side gate bus bar 300. In aspects, a dielectric material may be arranged in the gaps between the low side Kelvin bus bar 400 and the low side gate bus bar 500.

The at least one first position device 101 and the at least one second position device 102 may be one or more active devices, passive devices, dies, chips, transistors, and/or the like. In aspects, the at least one first position device 101 and the at least one second position device 102 may be implemented as one or more of the power semiconductor devices, a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a power MOSFET, a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a diode, a power Schottky diode, a gate-controlled thyristor, a Metal Insulator Semiconductor Field Effect Transistor (MISFET), and/or the like. The at least one first position device 101 and the at least one second position device 102 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems.

A power semiconductor device may refer to devices that include one or more power semiconductor die that are designed to carry large currents and/or that are capable of blocking high voltages. Herein, a power semiconductor die refers to a semiconductor die that during normal operation can pass at least 1 Amp of current and/or block at least 100 volts during reverse blocking operation. Power semiconductor die may be fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and/or the like. Power semiconductor die are often packaged to provide a packaged power semiconductor device.

A power MOSFET may be used power semiconductor die. A power MOSFET may be a three terminal device that has gate, drain and source terminals and a semiconductor layer structure that is often referred to as a semiconductor body. A source region and a drain region that are separated by a channel region are formed in the semiconductor body, and a gate electrode (which may act as the gate terminal or be electrically connected to the gate terminal) is disposed adjacent the channel region. The MOSFET may be turned on (to conduct current through the channel region between the source region and drain regions) by applying a bias voltage to the gate electrode, and may be turned off (to block current flow through the channel region) by removing the bias voltage (or reducing the bias voltage below a threshold level).

The substrate 104 may be implemented as a metal submount, a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The substrate 104 may include an insulating material, a dielectric material, and/or the like.

In aspects, the substrate 104 may be implemented as a power substrate that includes a ceramic substrate. In aspects, the power substrate may include a lower metal cladding layer formed on a lower side of the ceramic substrate, and an upper metal cladding layer may be formed on the upper side of the ceramic substrate. As used herein, the term “power substrate” refers to a dielectric substrate that has a metal cladding layer on both sides thereof. In aspects, the power substrate may be an Active Metal Brazed (AMB) power substrate, which includes first and second metal braze layers that may be used to bond first and second metal cladding layers, respectively, to the ceramic substrate. In aspects, the power substrate may be a Substrate (or, more typically, a Direct Bonded Copper (DBC) power substrate, as the metal cladding layers may typically be copper layers).

The power module 100 may include a base plate. The base plate may provide structural support to the power module 100 as well as facilitating heat spreading for thermal management of the power module 100. The base plate may include a base metal, such as copper, aluminum, or the like, or a metal matrix composite (MMC) which may provide coefficient of thermal expansion (CTE) matching to reduce thermally generated stress. In one aspect, the MMC material may be a composite of a high conductivity metal such as copper, aluminum, and the like, and either a low CTE metal such as molybdenum, beryllium, tungsten, and/or a nonmetal such as diamond, silicon carbide, beryllium oxide, graphite, embedded pyrolytic graphite, or the like. Depending on the material, the base plate may be formed by machining, casting, stamping, or the like. The base plate may have a metal plating, such as nickel, silver, gold and/or the like, to protect surfaces of the base plate and improve solder-ability. In one aspect, the base plate may have a flat backside. In one aspect, the base plate may have a convex profile to improve planarity after reflow. In one aspect, the base plate may have pin fins for direct cooling.

The substrate 104 may provide electrical interconnection, voltage isolation, heat transfer, and the like for the component of the power module 100. The substrate 104 may be constructed as a direct bond copper (DBC), an active metal braze (AMB), an insulated metal substrate (IMS), and/or the like. In the case of the IMS structure, the substrate 104 and the base plate may be integrated as the same element. In some aspects, the substrate 104 may be attached to the base plate with solder, thermally conductive epoxy, silver sintering or the like. In one aspect there may be two or more implementations of the substrate 104, one for each switch position.

In one aspect, the power module 100 may be implemented in a wide variety of power topologies, including half-bridge, full-bridge, three phase, booster, chopper, DC-DC converters, and like arrangements and/or topologies. In one aspect, one or more implementations of the power module 100 may be implemented in an application. The application may be a power system, a motor system, a motor drive, an automotive motor system, a charging system, an automotive charging system, a vehicle system, an industrial motor drive, an embedded motor drive, an uninterruptible power supply, an AC-DC power supply, a welder power supply, a military system, an inverter, an inverter for wind turbines, solar power panels, tidal power plants, electric vehicles (EVs), a converter, a solar inverter, a circuit breaker, a protection circuit, a DC-DC converter, an Off-Board DC Fast Charger for an electric vehicle (EV), an on-board DC/DC Converter for an electric vehicle (EV), an on-board battery charger for an electric vehicle (EV), an electric vehicle (EV) Powertrain/Main Inverter, an electric vehicle (EV) charging infrastructure, an electric traction motor, a motor drive for an electric motor, a commercial inductive heating system, an uninterruptible power system, a power system, a motor system, a motor drive, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, solar inverters, circuit breakers, protection circuits, DC-DC converters, Off-Board DC Fast Chargers for electric vehicles (EVs) and the like, on-board DC/DC Converters for electric vehicles (EVs) and the like, on-board battery chargers for electric vehicles (EVs) and the like, electric vehicle (EV) Powertrains/Main Inverters, electric vehicle (EV) charging infrastructures, electric traction motors, motor drives for electric motors, commercial inductive heating systems, uninterruptible power systems, and/or the like.

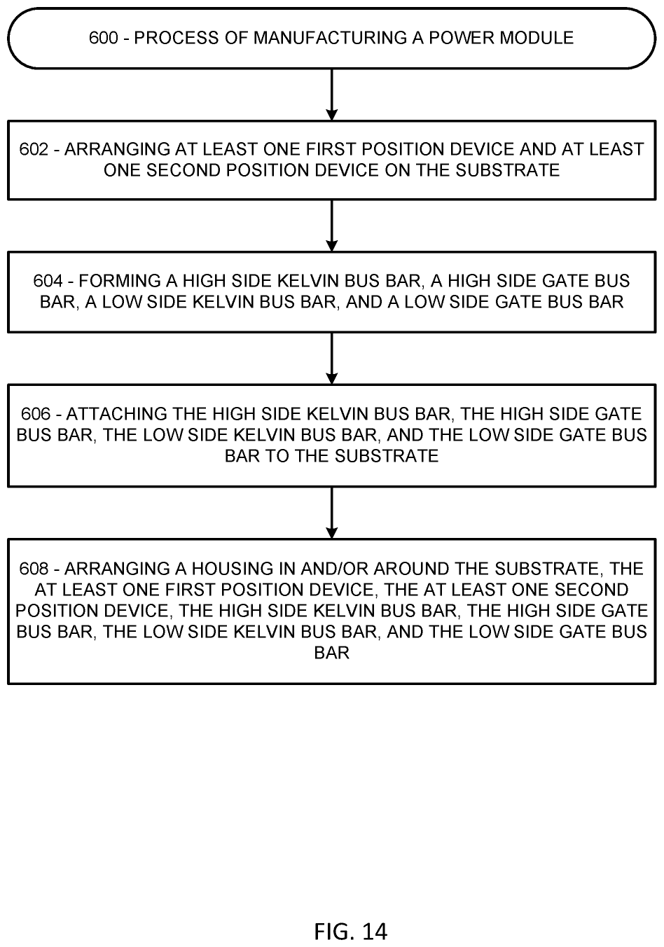

FIG. 14 illustrates a process of manufacturing a power module according to aspects of the disclosure.

In particular, FIG. 14 shows process of manufacturing a power module 600 according to aspects of the disclosure. In particular, it should be noted that the process of manufacturing a power module 600 is merely exemplary and may be modified consistent with the various aspects disclosed herein. Moreover, the process of manufacturing a power module 600 of the disclosure may include a process of implementing the power module 100. It should be noted that the process of manufacturing a power module 600 may be performed in a different order consistent with the aspects described above. Moreover, the process of manufacturing a power module 600 may be modified to have more or fewer process steps consistent with the various aspects disclosed herein.

The process of manufacturing a power module 600 of the disclosure may include arranging at least one first position device and at least one second position device on the substrate 602. In this regard, the arranging at least one first position device and at least one second position device on the substrate 602 may include any one or more materials, structures, arrangements, processes, and/or the like as described herein. Moreover, one or more proceeding or subsequent processes may also be implemented with respect to the arranging at least one first position device and at least one second position device on the substrate 602 consistent with the disclosure.

In particular aspects, the arranging at least one first position device and at least one second position device on the substrate 602 may include arranging the at least one first position device 101 and the at least one second position device 102 on the substrate 104 as disclosed herein with reference to FIGS. 1-12 and associated description.

The process of manufacturing a power module 600 of the disclosure may include forming a high side kelvin bus bar, a high side gate bus bar, a low side kelvin bus bar, and a low side gate bus bar 604. In this regard, the forming a high side kelvin bus bar, a high side gate bus bar, a low side kelvin bus bar, and a low side gate bus bar 604 may include any one or more materials, structures, arrangements, processes, and/or the like as described herein. Moreover, one or more proceeding or subsequent processes may also be implemented with respect to the forming a high side kelvin bus bar, a high side gate bus bar, a low side kelvin bus bar, and a low side gate bus bar 604 consistent with the disclosure.

In particular aspects, the forming a high side kelvin bus bar, a high side gate bus bar, a low side kelvin bus bar, and a low side gate bus bar 604 may include forming the high side Kelvin bus bar 200, the high side gate bus bar 300, the low side Kelvin bus bar 400, and the low side gate bus bar 500 as disclosed herein with reference to FIGS. 1-12 and associated description. In one or more aspects, the high side Kelvin bus bar 200, the high side gate bus bar 300, the low side Kelvin bus bar 400, and/or the low side gate bus bar 500 may comprise a metallic material such as copper, gold, nickel, palladium, silver, and the like, and combinations thereof. In aspects, the high side Kelvin bus bar 200, the high side gate bus bar 300, the low side Kelvin bus bar 400, and/or the low side gate bus bar 500 may be formed by one or more of extrusion, die forming, stamping, cutting, indenting, and/or the like. In aspects, the high side Kelvin bus bar 200, the high side gate bus bar 300, the low side Kelvin bus bar 400, and/or the low side gate bus bar 500 may be attached to the substrate 104 with a component attach that may include implementations of adhesive, soldering, sintering, eutectic bonding, ultrasonically welding, and/or the like as described herein. In aspects, the high side Kelvin connections 222 of the high side Kelvin bus bar 200, the high side gate connections 322 of the high side gate bus bar 300, the low side Kelvin connections 422 of the low side Kelvin bus bar 400, and/or the low side gate connections 522 of the low side gate bus bar 500 may be attached to the substrate 104 with a component attach that may include implementations of adhesive, soldering, sintering, eutectic bonding, ultrasonically welding, and/or the like as described herein.

The process of manufacturing a power module 600 of the disclosure may include attaching the high side kelvin bus bar, the high side gate bus bar, the low side kelvin bus bar, and the low side gate bus bar to the substrate 606. In this regard, the attaching the high side kelvin bus bar, the high side gate bus bar, the low side kelvin bus bar, and the low side gate bus bar to the substrate 606 may include any one or more materials, structures, arrangements, processes, and/or the like as described herein. Moreover, one or more proceeding or subsequent processes may also be implemented with respect to the attaching the high side kelvin bus bar, the high side gate bus bar, the low side kelvin bus bar, and the low side gate bus bar to the substrate 606 consistent with the disclosure.

In particular aspects, the attaching the high side kelvin bus bar, the high side gate bus bar, the low side kelvin bus bar, and the low side gate bus bar to the substrate 606 may include attaching the high side Kelvin bus bar 200, the high side gate bus bar 300, the low side Kelvin bus bar 400, and the low side gate bus bar 500 to the substrate 104 as disclosed herein with reference to FIGS. 1-12 and associated description.

The process of manufacturing a power module 600 of the disclosure may include arranging a housing in and/or around the substrate, the at least one first position device, the at least one second position device, the high side kelvin bus bar, the high side gate bus bar, the low side kelvin bus bar, and the low side gate bus bar 608. In this regard, the arranging a housing in and/or around the substrate, the at least one first position device, the at least one second position device, the high side kelvin bus bar, the high side gate bus bar, the low side kelvin bus bar, and the low side gate bus bar 608 may include any one or more materials, structures, arrangements, processes, and/or the like as described herein. Moreover, one or more proceeding or subsequent processes may also be implemented with respect to the arranging a housing in and/or around the substrate, the at least one first position device, the at least one second position device, the high side kelvin bus bar, the high side gate bus bar, the low side kelvin bus bar, and the low side gate bus bar 608 consistent with the disclosure.

In particular aspects, the arranging a housing in and/or around the substrate, the at least one first position device, the at least one second position device, the high side kelvin bus bar, the high side gate bus bar, the low side kelvin bus bar, and the low side gate bus bar 608 may include arranging the housing 110 in and/or around the substrate 104, the at least one first position device 101, the at least one second position device 102, the high side Kelvin bus bar 200, the high side gate bus bar 300, the low side Kelvin bus bar 400, and the low side gate bus bar 500 as disclosed herein with reference to FIGS. 1-12 and associated description. In one or more aspects, the housing 110 may comprise a molding compound that may substantially surround the parts of the power module 100 and may be formed of a plastic or a plastic polymer compound, which may be co-molded and/or an injection molded around the parts of the power module 100, thereby providing protection from the outside environment. The molding compound may be formed of a plastic, a mold compound, a plastic compound, a polymer, a polymer compound, a plastic polymer compound, an epoxy molding compound, and/or the like. The molding compound may be co-molded, injection molded, transfer molded, compression molded, and/or the like around the parts of the power module 100, from the outside environment.

The following are a number of nonlimiting EXAMPLES of aspects of the disclosure.

One EXAMPLE: a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the high side Kelvin bus bar, the high side gate bus bar, the low side Kelvin bus bar, and the low side gate bus bar are configured and arranged such that a high side signal loop inductance and a low side signal loop inductance are substantially equivalent.

The above-noted EXAMPLE may further include any one or a combination of more than one of the following EXAMPLES:

The power module of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The power module of the above-noted EXAMPLE where the low side gate bus bar and the low side Kelvin bus bar are arranged with a uniform gap therebetween to reduce the low side signal loop inductance; and where the high side gate bus bar and the high side Kelvin bus bar are arranged with a uniform gap therebetween to reduce the high side signal loop inductance. The power module of the above-noted EXAMPLE where one or more upper surfaces of the low side Kelvin bus bar and the low side gate bus bar are within a same plane to reduce the low side signal loop inductance; and where one or more lower surfaces of the low side Kelvin bus bar and the low side gate bus bar are within a same plane to reduce the low side signal loop inductance. The power module of the above-noted EXAMPLE where one or more upper surfaces of the high side Kelvin bus bar and the high side gate bus bar are arranged in a same plane to lower the low side signal loop inductance; and where one or more lower surfaces of the high side Kelvin bus bar and the high side gate bus bar are arranged in a same plane to lower the low side signal loop inductance. The power module of the above-noted EXAMPLE where one or more upper surfaces of the low side Kelvin bus bar and the low side gate bus bar are within a same plane to reduce the low side signal loop inductance; where one or more lower surfaces of the low side Kelvin bus bar and the low side gate bus bar are within a same plane to reduce the low side signal loop inductance; where one or more upper surfaces of the high side Kelvin bus bar and the high side gate bus bar are arranged in a same plane to lower the high side signal loop inductance; and where one or more lower surfaces of the high side Kelvin bus bar and the high side gate bus bar are arranged in a same plane to lower the high side signal loop inductance. The power module of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The power module of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The power module of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The power module of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The power module of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The power module of the above-noted EXAMPLE includes a housing, where portions of the high side Kelvin bus bar, the high side gate bus bar, the low side Kelvin bus bar, and the low side gate bus bar are embedded in the housing. The power module of the above-noted EXAMPLE includes a substrate, where the at least one first switch position device and the at least one second switch position device are arranged on a substrate. The power module of the above-noted EXAMPLE where portions of the high side Kelvin bus bar, the high side gate bus bar, the low side Kelvin bus bar, and the low side gate bus bar are attached to the substrate. The power module of the above-noted EXAMPLE where the at least one first switch position device and the at least one second switch position device includes at least one Metal Oxide Field Effect Transistor (MOSFET) and/or diode.

One EXAMPLE: a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the low side gate bus bar and the low side Kelvin bus bar are arranged with a uniform gap therebetween to reduce a low side signal loop inductance. The power module also includes where the high side gate bus bar and the high side Kelvin bus bar are arranged with a uniform gap therebetween to reduce a high side signal loop inductance.

The above-noted EXAMPLE may further include any one or a combination of more than one of the following EXAMPLES:

The power module of the above-noted EXAMPLE where the high side Kelvin bus bar, the high side gate bus bar, the low side Kelvin bus bar, and the low side gate bus bar are configured and arranged such that a high side signal loop inductance and a low side signal loop inductance are substantially equivalent. The power module of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The power module of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The power module of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The power module of the above-noted EXAMPLE where one or more upper surfaces of the low side Kelvin bus bar and the low side gate bus bar are within a same plane to reduce a low side signal loop inductance; where one or more lower surfaces of the low side Kelvin bus bar and the low side gate bus bar are within a same plane to reduce a low side signal loop inductance; where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The power module of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The power module of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The power module of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The power module of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The power module of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The power module of the above-noted EXAMPLE includes a housing, where portions of the high side Kelvin bus bar, the high side gate bus bar, the low side Kelvin bus bar, and the low side gate bus bar are embedded in the housing. The power module of the above-noted EXAMPLE includes a substrate, where the at least one first switch position device and the at least one second switch position device are arranged on a substrate. The power module of the above-noted EXAMPLE where portions of the high side Kelvin bus bar, the high side gate bus bar, the low side Kelvin bus bar, and the low side gate bus bar are attached to the substrate. The power module of the above-noted EXAMPLE where the at least one first switch position device and the at least one second switch position device includes at least one Metal Oxide Field Effect Transistor (MOSFET) and/or diode.

One EXAMPLE: a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device.

The power module in addition includes a low side gate bus bar configured to transmit gate signals to the at least one second switch position device. The power module moreover includes where one or more upper surfaces of the low side Kelvin bus bar and the low side gate bus bar are within a same plane to reduce a low side signal loop inductance. The power module also includes where one or more lower surfaces of the low side Kelvin bus bar and the low side gate bus bar are within a same plane to reduce a low side signal loop inductance. The power module further includes where one or more upper surfaces of the high side Kelvin bus bar and the high side gate bus bar are arranged in a same plane to lower a high side signal loop inductance. The power module in addition includes where one or more lower surfaces of the high side Kelvin bus bar and the high side gate bus bar are arranged in a same plane to lower a high side signal loop inductance.

The above-noted EXAMPLE may further include any one or a combination of more than one of the following EXAMPLES:

The power module of the above-noted EXAMPLE where the high side Kelvin bus bar, the high side gate bus bar, the low side Kelvin bus bar, and the low side gate bus bar are configured and arranged such that a high side signal loop inductance and a low side signal loop inductance are substantially equivalent. The power module of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The power module of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The power module of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The power module of the above-noted EXAMPLE where the low side gate bus bar and the low side Kelvin bus bar are arranged with a uniform gap therebetween to reduce a low side signal loop inductance; and where the high side gate bus bar and the high side Kelvin bus bar are arranged with a uniform gap therebetween to reduce a high side signal loop inductance. The power module of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The power module of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The power module of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The power module of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The power module of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The power module of the above-noted EXAMPLE includes a housing, where portions of the high side Kelvin bus bar, the high side gate bus bar, the low side Kelvin bus bar, and the low side gate bus bar are embedded in the housing. The power module of the above-noted EXAMPLE includes a substrate, where the at least one first switch position device and the at least one second switch position device are arranged on a substrate. The power module of the above-noted EXAMPLE where portions of the high side Kelvin bus bar, the high side gate bus bar, the low side Kelvin bus bar, and the low side gate bus bar are attached to the substrate. The power module of the above-noted EXAMPLE where the at least one first switch position device and the at least one second switch position device includes at least one Metal Oxide Field Effect Transistor (MOSFET) and/or diode.

One EXAMPLE: a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes configuring and arranging the high side Kelvin bus bar, the high side gate bus bar, the low side Kelvin bus bar, and the low side gate bus bar such that a high side signal loop inductance and a low side signal loop inductance are substantially equivalent.

The above-noted EXAMPLE may further include any one or a combination of more than one of the following EXAMPLES:

The process of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The process of the above-noted EXAMPLE includes: configuring and arranging the low side gate bus bar and the low side Kelvin bus bar with a uniform gap therebetween to reduce a low side signal loop inductance; and configuring and arranging the high side gate bus bar and the high side Kelvin bus bar with a uniform gap therebetween to reduce a high side signal loop inductance. The process of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The process of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The process of the above-noted EXAMPLE includes: arranging one or more upper surfaces of the low side Kelvin bus bar and the low side gate bus bar within a same plane to reduce a low side signal loop inductance; arranging one or more lower surfaces of the low side Kelvin bus bar and the low side gate bus bar within a same plane to reduce a low side signal loop inductance; arranging one or more upper surfaces of the high side Kelvin bus bar and the high side gate bus bar within a same plane to lower a high side signal loop inductance; and arranging one or more lower surfaces of the high side Kelvin bus bar and the high side gate bus bar within in a same plane to lower a high side signal loop inductance. The process of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The process of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The process of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The process of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The process of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The process of the above-noted EXAMPLE includes a housing, where portions of the high side Kelvin bus bar, the high side gate bus bar, the low side Kelvin bus bar, and the low side gate bus bar are embedded in the housing. The process of the above-noted EXAMPLE includes a substrate, where the at least one first switch position device and the at least one second switch position device are arranged on a substrate. The process of the above-noted EXAMPLE where portions of the high side Kelvin bus bar, the high side gate bus bar, the low side Kelvin bus bar, and the low side gate bus bar are attached to the substrate. The process of the above-noted EXAMPLE where the at least one first switch position device and the at least one second switch position device includes at least one Metal Oxide Field Effect Transistor (MOSFET) and/or diode.

One EXAMPLE: a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes configuring and arranging the low side gate bus bar and the low side Kelvin bus bar with a uniform horizontal gap therebetween to reduce a low side signal loop inductance. The process also includes configuring and arranging the high side gate bus bar and the high side Kelvin bus bar with a uniform horizontal gap therebetween to reduce a high side signal loop inductance.

The above-noted EXAMPLE may further include any one or a combination of more than one of the following EXAMPLES:

The process of the above-noted EXAMPLE includes configuring and arranging the high side Kelvin bus bar, the high side gate bus bar, the low side Kelvin bus bar, and the low side gate bus bar such that a high side signal loop inductance and a low side signal loop inductance are substantially equivalent. The process of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The process of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The process of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The process of the above-noted EXAMPLE includes: arranging one or more upper surfaces of the low side Kelvin bus bar and the low side gate bus bar within a same plane to reduce a low side signal loop inductance; arranging one or more lower surfaces of the low side Kelvin bus bar and the low side gate bus bar within a same plane to reduce a low side signal loop inductance; arranging one or more upper surfaces of the high side Kelvin bus bar and the high side gate bus bar within a same plane to lower a high side signal loop inductance; and arranging one or more lower surfaces of the high side Kelvin bus bar and the high side gate bus bar within in a same plane to lower a high side signal loop inductance. The process of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The process of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The process of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The process of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The process of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The process of the above-noted EXAMPLE includes a housing, where portions of the high side Kelvin bus bar, the high side gate bus bar, the low side Kelvin bus bar, and the low side gate bus bar are embedded in the housing. The process of the above-noted EXAMPLE includes a substrate, where the at least one first switch position device and the at least one second switch position device are arranged on a substrate. The process of the above-noted EXAMPLE where portions of the high side Kelvin bus bar, the high side gate bus bar, the low side Kelvin bus bar, and the low side gate bus bar are attached to the substrate. The process of the above-noted EXAMPLE where the at least one first switch position device and the at least one second switch position device includes at least one Metal Oxide Field Effect Transistor (MOSFET) and/or diode.

One EXAMPLE: a process includes providing at least one first switch position device. The process in addition includes providing at least one second switch position device. The process moreover includes configuring a high side Kelvin bus bar to transmit Kelvin signals to the at least one first switch position device. The process also includes configuring a high side gate bus bar to transmit gate signals to the at least one first switch position device. The process further includes configuring a low side Kelvin bus bar to transmit Kelvin signals to the at least one second switch position device. The process in addition includes configuring a low side gate bus bar to transmit gate signals to the at least one second switch position device. The process moreover includes arranging one or more upper surfaces of the low side Kelvin bus bar and the low side gate bus bar within a same plane to reduce a low side signal loop inductance. The process also includes arranging one or more lower surfaces of the low side Kelvin bus bar and the low side gate bus bar within a same plane to reduce a low side signal loop inductance. The process further includes arranging one or more upper surfaces of the high side Kelvin bus bar and the high side gate bus bar within a same plane to lower a high side signal loop inductance. The process in addition includes arranging one or more lower surfaces of the high side Kelvin bus bar and the high side gate bus bar within in a same plane to lower a high side signal loop inductance.

The above-noted EXAMPLE may further include any one or a combination of more than one of the following EXAMPLES:

The process of the above-noted EXAMPLE where the high side Kelvin bus bar, the high side gate bus bar, the low side Kelvin bus bar, and the low side gate bus bar are configured and arranged such that a high side signal loop inductance and a low side signal loop inductance are substantially equivalent. The process of the above-noted EXAMPLE where the low side signal loop inductance includes a low side Kelvin bus bar inductance and a low side gate bus bar inductance combined together with a deduction of a low side mutual inductance; and where the high side signal loop inductance includes a high side Kelvin bus bar inductance and a high side gate bus bar inductance combined together with a deduction of a high side mutual inductance. The process of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The process of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The process of the above-noted EXAMPLE includes: configuring and arranging the low side gate bus bar and the low side Kelvin bus bar with a uniform gap therebetween to reduce a low side signal loop inductance; and configuring and arranging the high side gate bus bar and the high side Kelvin bus bar with a uniform gap therebetween to reduce a high side signal loop inductance. The process of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The process of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The process of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The process of the above-noted EXAMPLE where at least one of the high side Kelvin bus bar, the high side gate bus bar, the low side Kelvin bus bar, and the low side gate bus bar includes at least one lateral portion and at least one longitudinal portion; and where the inductance adjustment structure includes a greater vertical height than a vertical height of the at least one lateral portion and the at least one longitudinal portion. The process of the above-noted EXAMPLE where the high side Kelvin bus bar, the high side gate bus bar, the low side Kelvin bus bar, and the low side gate bus bar each includes at least one lateral portion and at least one longitudinal portion; and where a vertical dimension of the at least one lateral portion and the at least one longitudinal portion is at least 20% of a power module vertical height. The process of the above-noted EXAMPLE includes a housing, where portions of the high side Kelvin bus bar, the high side gate bus bar, the low side Kelvin bus bar, and the low side gate bus bar are embedded in the housing. The process of the above-noted EXAMPLE includes a substrate, where the at least one first switch position device and the at least one second switch position device are arranged on a substrate. The process of the above-noted EXAMPLE where portions of the high side Kelvin bus bar, the high side gate bus bar, the low side Kelvin bus bar, and the low side gate bus bar are attached to the substrate. The process of the above-noted EXAMPLE where the at least one first switch position device and the at least one second switch position device includes at least one Metal Oxide Field Effect Transistor (MOSFET) and/or diode.

One EXAMPLE: a power module includes at least one first switch position device. The power module in addition includes at least one second switch position device. The power module moreover includes a high side Kelvin bus bar configured to transmit Kelvin signals to the at least one first switch position device. The power module also includes a high side gate bus bar configured to transmit gate signals to the at least one first switch position device. The power module further includes a low side Kelvin bus bar configured to transmit Kelvin signals to the at least one second switch position device. The power module in addition includes a low side gate bus bar configured to transmit gate signals to the at least one second switch position device. The power module moreover includes where the high side Kelvin bus bar, the high side gate bus bar, the low side Kelvin bus bar, and the low side gate bus bar each includes at least one lateral portion and at least one longitudinal portion. The power module also includes where a vertical dimension of the at least one lateral portion and the at least one longitudinal portion is at least 20% of a power module vertical height.

The above-noted EXAMPLE may further include any one or a combination of more than one of the following EXAMPLES:

The power module of the above-noted EXAMPLE where the high side Kelvin bus bar, the high side gate bus bar, the low side Kelvin bus bar, and the low side gate bus bar are configured and arranged such that a high side signal loop inductance and a low side signal loop inductance are substantially equivalent. The power module of the above-noted EXAMPLE where the low side gate bus bar and the low side Kelvin bus bar are arranged with a uniform gap therebetween to reduce a low side signal loop inductance; and where the high side gate bus bar and the high side Kelvin bus bar are arranged with a uniform gap therebetween to reduce a high side signal loop inductance. The power module of the above-noted EXAMPLE where one or more upper surfaces of the low side Kelvin bus bar and the low side gate bus bar are within a same plane to reduce a low side signal loop inductance; and where one or more lower surfaces of the low side Kelvin bus bar and the low side gate bus bar are within a same plane to reduce a low side signal loop inductance. The power module of the above-noted EXAMPLE where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The power module of the above-noted EXAMPLE where one or more upper surfaces of the low side Kelvin bus bar and the low side gate bus bar are within a same plane to reduce a low side signal loop inductance; where one or more lower surfaces of the low side Kelvin bus bar and the low side gate bus bar are within a same plane to reduce a low side signal loop inductance; where one or more upper surfaces of the high side Kelvin bus bar and the high side gate bus bar are arranged in a same plane to lower a high side signal loop inductance; and where one or more lower surfaces of the high side Kelvin bus bar and the high side gate bus bar are arranged in a same plane to lower a high side signal loop inductance. The power module of the above-noted EXAMPLE where a vertical portion of one of the low side gate bus bar and the low side Kelvin bus bar is laterally adjacent a portion of a lateral portion of the other one of the low side gate bus bar and the low side Kelvin bus bar. The power module of the above-noted EXAMPLE where a vertical portion of one of the high side gate bus bar and the high side Kelvin bus bar is laterally adjacent a portion of a lateral portion of the other one of the high side gate bus bar and the high side Kelvin bus bar. The power module of the above-noted EXAMPLE where at least one of the high side Kelvin bus bar, the high side gate bus bar, the low side Kelvin bus bar, and the low side gate bus bar includes an inductance adjustment structure configured to adjust inductance of the at least one of the high side Kelvin bus bar, the high side gate bus bar, the low side Kelvin bus bar, and the low side gate bus bar. The power module of the above-noted EXAMPLE where the inductance adjustment structure includes a greater vertical height than a vertical height of the at least one lateral portion and the at least one longitudinal portion. The power module of the above-noted EXAMPLE where the high side Kelvin bus bar and the high side gate bus bar are configured and arranged to have a substantially equivalent inductance; and where the low side Kelvin bus bar and the low side gate bus bar are configured and arranged to have a substantially equivalent inductance. The power module of the above-noted EXAMPLE includes a housing, where portions of the high side Kelvin bus bar, the high side gate bus bar, the low side Kelvin bus bar, and the low side gate bus bar are embedded in the housing. The power module of the above-noted EXAMPLE includes a substrate, where the at least one first switch position device and the at least one second switch position device are arranged on a substrate. The power module of the above-noted EXAMPLE where portions of the high side Kelvin bus bar, the high side gate bus bar, the low side Kelvin bus bar, and the low side gate bus bar are attached to the substrate. The power module of the above-noted EXAMPLE where the at least one first switch position device and the at least one second switch position device includes at least one Metal Oxide Field Effect Transistor (MOSFET) and/or diode.

Accordingly, the disclosure as set forth a power module 100 having implementations of the high side Kelvin bus bar 200, the high side gate bus bar 300, the low side Kelvin bus bar 400, and/or the low side gate bus bar 500 that may reduce manufacturing cost, manufacturing complexity, and/or the like. Further, the disclosure as set forth a power module 100 where the high side Kelvin bus bar 200, the high side gate bus bar 300, the low side Kelvin bus bar 400, and/or the low side gate bus bar 500 may be optimized as taught by the disclosure to concurrently achieve near perfect matching and significantly lower inductances. Additionally, the disclosure as set forth a power module 100 having faster charging of the input capacitance of the at least one first position device 101 and the at least one second position device 102, quicker turn-on of the at least one first position device 101 and the at least one second position device 102, and increases the resonant frequency of the G-SK loops (Gate-Source Kelvin), for example with Ls and input capacitance.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power module comprising:
at least one first switch position device;
at least one second switch position device;
a high side Kelvin bus bar configured to transmit Kelvin signals to the at least one first switch position device;
a high side gate bus bar configured to transmit gate signals to the at least one first switch position device;
a low side Kelvin bus bar configured to transmit Kelvin signals to the at least one second switch position device; and
a low side gate bus bar configured to transmit gate signals to the at least one second switch position device,
wherein the high side Kelvin bus bar, the high side gate bus bar, the low side Kelvin bus bar, and the low side gate bus bar are configured and arranged such that a high side signal loop inductance and a low side signal loop inductance are substantially equivalent.

2. The power module according to claim 1
wherein the low side signal loop inductance comprises a low side Kelvin bus bar inductance and a low side gate bus bar inductance combined together with a deduction of a low side mutual inductance; and
wherein the high side signal loop inductance comprises a high side Kelvin bus bar inductance and a high side gate bus bar inductance combined together with a deduction of a high side mutual inductance.

3. The power module according to claim 1
wherein the low side gate bus bar and the low side Kelvin bus bar are arranged with a uniform gap therebetween to reduce the low side signal loop inductance; and
wherein the high side gate bus bar and the high side Kelvin bus bar are arranged with a uniform gap therebetween to reduce the high side signal loop inductance.

4. The power module according to claim 1
wherein one or more upper surfaces of the low side Kelvin bus bar and the low side gate bus bar are within a same plane to reduce the low side signal loop inductance; and
wherein one or more lower surfaces of the low side Kelvin bus bar and the low side gate bus bar are within a same plane to reduce the low side signal loop inductance.

5. The power module according to claim 1
wherein one or more upper surfaces of the high side Kelvin bus bar and the high side gate bus bar are arranged in a same plane to lower the low side signal loop inductance; and
wherein one or more lower surfaces of the high side Kelvin bus bar and the high side gate bus bar are arranged in a same plane to lower the low side signal loop inductance.

6. The power module according to claim 1
wherein one or more upper surfaces of the low side Kelvin bus bar and the low side gate bus bar are within a same plane to reduce the low side signal loop inductance;
wherein one or more lower surfaces of the low side Kelvin bus bar and the low side gate bus bar are within a same plane to reduce the low side signal loop inductance;
wherein one or more upper surfaces of the high side Kelvin bus bar and the high side gate bus bar are arranged in a same plane to lower the high side signal loop inductance; and
wherein one or more lower surfaces of the high side Kelvin bus bar and the high side gate bus bar are arranged in a same plane to lower the high side signal loop inductance.

7. The power module according to claim 1 wherein a vertical portion of one of the low side gate bus bar and the low side Kelvin bus bar is laterally adjacent a portion of a lateral portion of the other one of the low side gate bus bar and the low side Kelvin bus bar.

8. The power module according to claim 1 wherein a vertical portion of one of the high side gate bus bar and the high side Kelvin bus bar is laterally adjacent a portion of a lateral portion of the other one of the high side gate bus bar and the high side Kelvin bus bar.

9. The power module according to claim 1 wherein at least one of the high side Kelvin bus bar, the high side gate bus bar, the low side Kelvin bus bar, and the low side gate bus bar comprise an inductance adjustment structure configured to adjust inductance of the at least one of the high side Kelvin bus bar, the high side gate bus bar, the low side Kelvin bus bar, and the low side gate bus bar.

10. The power module according to claim 9
wherein at least one of the high side Kelvin bus bar, the high side gate bus bar, the low side Kelvin bus bar, and the low side gate bus bar comprises at least one lateral portion and at least one longitudinal portion; and
wherein the inductance adjustment structure comprises a greater vertical height than a vertical height of the at least one lateral portion and the at least one longitudinal portion.

11. The power module according to claim 1
wherein the high side Kelvin bus bar, the high side gate bus bar, the low side Kelvin bus bar, and the low side gate bus bar each comprise at least one lateral portion and at least one longitudinal portion; and
wherein a vertical dimension of the at least one lateral portion and the at least one longitudinal portion is at least 20% of a power module vertical height.

12. The power module according to claim 1
wherein the low side Kelvin bus bar and the low side gate bus bar are structured and arranged to reduce the low side signal loop inductance to less than 40 nH; and
wherein the high side gate bus bar and the high side Kelvin bus bar are structured and arranged to reduce the high side signal loop inductance to less than 40 nH.

13. The power module according to claim 1
wherein the low side Kelvin bus bar and the low side gate bus bar are structured and arranged to reduce the low side signal loop inductance to 5 nH-40 nH; and
wherein the high side gate bus bar and the high side Kelvin bus bar are structured and arranged to reduce the high side signal loop inductance to 5 nH-40 nH.

14. The power module according to claim 1 further comprising a housing,
wherein portions of the high side Kelvin bus bar, the high side gate bus bar, the low side Kelvin bus bar, and the low side gate bus bar are embedded in the housing.

15. The power module according to claim 1 further comprising a substrate,
wherein the at least one first switch position device and the at least one second switch position device are arranged on a substrate.

16. The power module according to claim 15 wherein portions of the high side Kelvin bus bar, the high side gate bus bar, the low side Kelvin bus bar, and the low side gate bus bar are attached to the substrate.

17. The power module according to claim 1 wherein the at least one first switch position device and the at least one second switch position device comprise at least one Metal Oxide Field Effect Transistor (MOSFET) and/or diode.

18. A power module comprising:
at least one first switch position device;
at least one second switch position device;
a high side Kelvin bus bar configured to transmit Kelvin signals to the at least one first switch position device;
a high side gate bus bar configured to transmit gate signals to the at least one first switch position device;
a low side Kelvin bus bar configured to transmit Kelvin signals to the at least one second switch position device; and
a low side gate bus bar configured to transmit gate signals to the at least one second switch position device,
wherein the low side gate bus bar and the low side Kelvin bus bar are arranged with a uniform gap therebetween to reduce a low side signal loop inductance; and
wherein the high side gate bus bar and the high side Kelvin bus bar are arranged with a uniform gap therebetween to reduce a high side signal loop inductance.

19. The power module according to claim 18 wherein the high side Kelvin bus bar, the high side gate bus bar, the low side Kelvin bus bar, and the low side gate bus bar are configured and arranged such that a high side signal loop inductance and a low side signal loop inductance are substantially equivalent.

20. The power module according to claim 19
wherein the low side signal loop inductance comprises a low side Kelvin bus bar inductance and a low side gate bus bar inductance combined together with a deduction of a low side mutual inductance; and
wherein the high side signal loop inductance comprises a high side Kelvin bus bar inductance and a high side gate bus bar inductance combined together with a deduction of a high side mutual inductance.

21.-34. (canceled)

35. A power module comprising:
at least one first switch position device;
at least one second switch position device;
a high side Kelvin bus bar configured to transmit Kelvin signals to the at least one first switch position device;
a high side gate bus bar configured to transmit gate signals to the at least one first switch position device;
a low side Kelvin bus bar configured to transmit Kelvin signals to the at least one second switch position device; and
a low side gate bus bar configured to transmit gate signals to the at least one second switch position device,
wherein one or more upper surfaces of the low side Kelvin bus bar and the low side gate bus bar are within a same plane to reduce a low side signal loop inductance;
wherein one or more lower surfaces of the low side Kelvin bus bar and the low side gate bus bar are within a same plane to reduce a low side signal loop inductance;
wherein one or more upper surfaces of the high side Kelvin bus bar and the high side gate bus bar are arranged in a same plane to lower a high side signal loop inductance; and
wherein one or more lower surfaces of the high side Kelvin bus bar and the high side gate bus bar are arranged in a same plane to lower a high side signal loop inductance.

36. The power module according to claim 35 wherein the high side Kelvin bus bar, the high side gate bus bar, the low side Kelvin bus bar, and the low side gate bus bar are configured and arranged such that a high side signal loop inductance and a low side signal loop inductance are substantially equivalent.

37. (canceled)

38. (canceled)

39. The power module according to claim 35
wherein one or more upper surfaces of the high side Kelvin bus bar and the high side gate bus bar are arranged in a same plane to lower a high side signal loop inductance; and
wherein one or more lower surfaces of the high side Kelvin bus bar and the high side gate bus bar are arranged in a same plane to lower a high side signal loop inductance.

40.-102. (canceled)

103. A power module comprising:
at least one first switch position device;
at least one second switch position device;
a high side Kelvin bus bar configured to transmit Kelvin signals to the at least one first switch position device;
a high side gate bus bar configured to transmit gate signals to the at least one first switch position device;
a low side Kelvin bus bar configured to transmit Kelvin signals to the at least one second switch position device; and
a low side gate bus bar configured to transmit gate signals to the at least one second switch position device,
wherein the high side Kelvin bus bar, the high side gate bus bar, the low side Kelvin bus bar, and the low side gate bus bar each comprise at least one lateral portion and at least one longitudinal portion; and
wherein a vertical dimension of the at least one lateral portion and the at least one longitudinal portion is at least 20% of a power module vertical height.

104. The power module according to claim 103 wherein the high side Kelvin bus bar, the high side gate bus bar, the low side Kelvin bus bar, and the low side gate bus bar are configured and arranged such that a high side signal loop inductance and a low side signal loop inductance are substantially equivalent.

105. The power module according to claim 103
wherein the low side gate bus bar and the low side Kelvin bus bar are arranged with a uniform gap therebetween to reduce a low side signal loop inductance; and
wherein the high side gate bus bar and the high side Kelvin bus bar are arranged with a uniform gap therebetween to reduce a high side signal loop inductance.

106. The power module according to claim 103
wherein one or more upper surfaces of the low side Kelvin bus bar and the low side gate bus bar are within a same plane to reduce a low side signal loop inductance; and
wherein one or more lower surfaces of the low side Kelvin bus bar and the low side gate bus bar are within a same plane to reduce a low side signal loop inductance.

107.-119. (canceled)
